(19) United States
(12) Patent Application Publication
(10) Pub. No.: US 2026/0182127 A1
(43) Pub. Date: Jun. 25, 2026

(54) DISPLAY DEVICE AND ELECTRONIC DEVICES INCLUDING THE SAME

(71) Applicant: Samsung Display Co., LTD., Yongin-si (KR)

(72) Inventors: Changil TAE, Yongin-si (KR); Gyujeong LEE, Yongin-si (KR); Jaeyeon JEONG, Yongin-si (KR)

(21) Appl. No.: 19/427,200

(22) Filed: Dec. 19, 2025

(30) Foreign Application Priority Data
Dec. 20, 2024 (KR) 10-2024-0193314

(51) Int. Cl. H10H 29/853; H10H 20/857; H10H 29/37; H10H 29/49; H10H 29/85

(52) U.S. Cl. CPC H10H 29/853; H10H 20/857; H10H 29/37; H10H 29/49; H10H 29/8508

(57) ABSTRACT

A display device includes a plurality of island portions disposed to be spaced apart from each other and including a pixel circuit, and a plurality of bridge portions, each connecting adjacent island portions among the plurality of island portions to each other, wherein each of the plurality of island portions includes a first light-emitting element and a second light-emitting element, which are disposed on the island portion and spaced apart from each other, and a first organic pattern partially overlapping the first light-emitting element and the second light-emitting element in a plan view and continuously disposed on the first light-emitting element and the second light-emitting element to extend in a first direction.

This application claims priority to Korean Patent Application No. 10-2024-0193314, filed on Dec. 20, 2024, and all the benefits accruing therefrom under 35 U.S.C. § 119, the content of which in its entirety is herein incorporated by reference.

### BACKGROUND

### 1. Technical Field

One or more embodiments of the disclosure relate to a display device, for example, a flexible display device.

### 2. Background Art

According to the development of display devices visually displaying electrical signals, various display devices having excellent characteristics, such as reduced thickness, reduced weight, and low power consumption, have been introduced. For example, flexible display devices that can be folded or rolled into a roll shape have been introduced. Recently, research and development on display devices having various structures, such as stretchable display devices that can be changed into various shapes, have been actively conducted.

### SUMMARY

### Technical Problem

One or more embodiments of the disclosure provide a display device, for example, a flexible display device.

### Solution to Problem

According to an aspect of the disclosure, provided is a display device including a plurality of island portions disposed to be spaced apart from each other and including a pixel circuit, and a plurality of bridge portions, each connecting adjacent island portions among the plurality of island portions to each other, where each of the plurality of island portions includes a first light-emitting element and a second light-emitting element, which are disposed on the island portion and spaced apart from each other, and a first organic pattern partially overlapping the first light-emitting element and the second light-emitting element in a plan view and continuously disposed on the first light-emitting element and the second light-emitting element to extend in a first direction.

According to an embodiment of the disclosure, the display device may further include a second organic pattern including a same material as the first organic pattern and disposed to surround edges of the island portion in a frame shape.

According to an embodiment of the disclosure, the first organic pattern and the second organic pattern may be provided as an integral body.

According to an embodiment of the disclosure, the display device may further include a third organic pattern including the same material as the first organic pattern and disposed on each of the plurality of bridge portions.

According to an embodiment of the disclosure, the first organic pattern, the second organic pattern, and the third organic pattern may be provided as an integral body.

According to an embodiment of the disclosure, each of the first light-emitting element and the second light-emitting element may include an inorganic light-emitting element.

According to an embodiment of the disclosure, each of the first light-emitting element and the second light-emitting element may include a first semiconductor layer, a second semiconductor layer, an intermediate layer disposed between the first semiconductor layer and the second semiconductor layer, a first electrode positioned on the first semiconductor layer, and a second electrode positioned on the second semiconductor layer.

According to an embodiment, the first organic pattern may be disposed to pass between the first electrode and the second electrode, and the first electrode and the second electrode may be spaced apart from each other.

According to an embodiment, the first organic pattern may not overlap the first electrode and the second electrode in the plan view.

According to an embodiment of the disclosure, the island portion may further include a substrate and an organic insulating film positioned on the substrate, the pixel circuit may be disposed on the substrate, the organic insulating film may be disposed on the pixel circuit, and at least a portion of each of the first light-emitting element and the second light-emitting element may be surrounded and embedded in the organic insulating film.

According to an embodiment of the disclosure, the first electrode and the second electrode may protrude above an upper surface of the organic insulating film.

According to an embodiment of the disclosure, the pixel circuit may include a first electrode pad and a second electrode pad, and the organic insulating film may define a first contact hole and a second contact hole therein exposing the first electrode pad and the second electrode pad, respectively.

According to an embodiment of the disclosure, the display device may further include a first contact electrode electrically connecting the first electrode pad to the first electrode, and a second contact electrode electrically connecting the second electrode pad to the second electrode. According to an embodiment, the first contact electrode may contact the first electrode pad in the first contact hole, and the second contact electrode may contact the second electrode pad in the second contact hole. According to an embodiment of the disclosure, each of the first contact electrode and the second contact electrode may include a transparent conductive material.

According to an embodiment, the first organic pattern may pass between the first electrode and the second electrode.

According to an embodiment of the disclosure, a width of the first organic pattern may be equal to or less than a distance between the first electrode and the second electrode.

According to an embodiment of the disclosure, a top surface of the first organic pattern may be positioned higher than top surfaces of the first electrode and the second electrode.

According to an embodiment of the disclosure, each of the plurality of bridge portions may have a serpentine shape in the plan view.

According to an aspect of the disclosure, provided is an electronic device including a display device, the display device includes a plurality of island portions disposed to be spaced apart from each other and including a pixel circuit, and a plurality of bridge portions, each connecting adjacent island portions among the plurality of island portions to each other, where each of the plurality of island portions includes a first light-emitting element and a second light-emitting element, which are disposed on the island portion and spaced apart from each other, and an organic pattern partially overlapping the first light-emitting element and the second light-emitting element in a plan view and continuously disposed on the first light-emitting element and the second light-emitting element to extend in a first direction.

Other aspects, features, and advantages other than those described above will now become apparent from the following drawings, claims, and the detailed description of the disclosure.

These general and specific aspects may be embodied using a system, a method, a computer program, or a combination of any system, method, and computer program.

### Advantageous Effects of Invention

According to an embodiment of the disclosure, a display device which may prevent damage caused by concentration of stress and may be stretched and recovered in various directions may be provided. These effects are examples, and the scope of the disclosure is not limited thereto.

### BRIEF DESCRIPTION OF DRAWINGS

FIG. 1 is a schematic perspective view of a display device according to an embodiment of the disclosure.

FIGS. 2A and 2B are perspective views each illustrating a state in which the display device of FIG. 1 is stretched in a first direction.

FIG. 2C is a perspective view illustrating a state in which the display device of FIG. 1 is stretched in a second direction.

FIG. 2D is a perspective view illustrating a state in which the display device of FIG. 1 is stretched in the first direction and the second direction.

FIG. 2E is a perspective view illustrating a state in which the display device of FIG. 1 is stretched in a third direction.

FIG. 3 is a schematic plan view of a display device according to an embodiment of the disclosure.

FIGS. 4A to 4C are enlarged plan views of a display device, as a portion of a display device according to an embodiment of the disclosure.

FIG. 5 is a schematic cross-sectional view of a first island portion and a first bridge portion, which are disposed in a display area of a display device according to an embodiment of the disclosure.

FIGS. 6A to 6C are equivalent circuit diagrams each illustrating a sub-pixel of a display device according to an embodiment of the disclosure.

FIGS. 7A to 7C are schematic enlarged plan views of a first island portion and a first bridge portion, which are disposed in a display area of a display device according to an embodiment of the disclosure.

FIGS. 8A to 8C are schematic cross-sectional views of light-emitting elements of a display device according to an embodiment of the disclosure.

FIG. 9 is an enlarged cross-sectional view schematically illustrating a portion of a display device according to an embodiment of the disclosure.

FIG. 10 is a schematic cross-sectional view of a portion of a display area of a display device according to an embodiment of the disclosure.

FIGS. 11A to 11F are cross-sectional views schematically illustrating processes of manufacturing a display device according to an embodiment of the disclosure.

FIGS. 12A to 12C are cross-sectional views schematically illustrating processes of manufacturing a display device according to an embodiment of the disclosure.

FIG. 13A is a schematic perspective view of an electronic device including a display device according to an embodiment of the disclosure.

FIG. 13B is a schematic block diagram of an electronic device including a display device according to an embodiment of the disclosure.

FIGS. 14A to 14D are schematic perspective views showing embodiments of an electronic device including a display device, respectively, according to an embodiment of the disclosure.

FIGS. 15A to 15E are schematic perspective views illustrating electronic devices, respectively, according to an embodiment of the disclosure.

### DETAILED DESCRIPTION

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the disclosure, while such terms as “first,” “second,” etc., may be used to describe various elements, such elements must not be limited to the above terms.

In the disclosure, an expression used in the singular encompasses the expression of the plural, unless it has a clearly different meaning in the context.

In the disclosure, it is to be understood that the terms such as “including” and “having” are intended to indicate the existence of the features or elements disclosed in the present disclosure, and are not intended to preclude the possibility that one or more other features or elements may exist or may be added.

In the disclosure, it will be understood that when a layer, region, or component is referred to as being formed on another layer, region, or component, it can be directly or indirectly formed on the other layer, region, or component. That is, for example, intervening layers, regions, or components may be present.

In the disclosure, it will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

In the disclosure, “A and/or B” may include “A,” “B,” or “A and B.” In addition, “at least one of A and B” or “at least one selected from A and B” may include “A,” “B,” or “A and B.”

In the disclosure, the x axis, the y axis, and the z axis are not limited to three rows on the orthogonal coordinates system, and may be interpreted in a broad sense including the same. For example, the x-axis, the y-axis, and the z-axis may be perpendicular to one another, or may represent different directions that are not perpendicular to one another.

In the disclosure, when a certain embodiment may be implemented differently, a specific process order may be performed differently from the described order. For example, two consecutively described processes may be performed substantially at the same time or performed in an order opposite to the described order.

Sizes of elements in the drawings may be exaggerated or reduced for convenience of explanation. For example, since sizes and thicknesses of components in the drawings are arbitrarily illustrated for convenience of explanation, the following embodiments are not limited thereto.

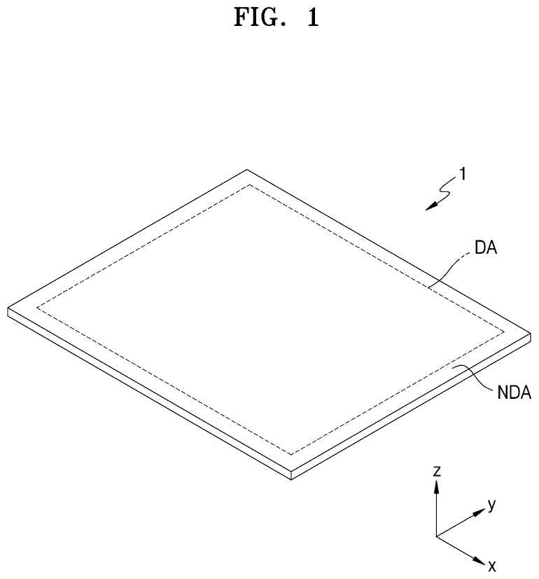

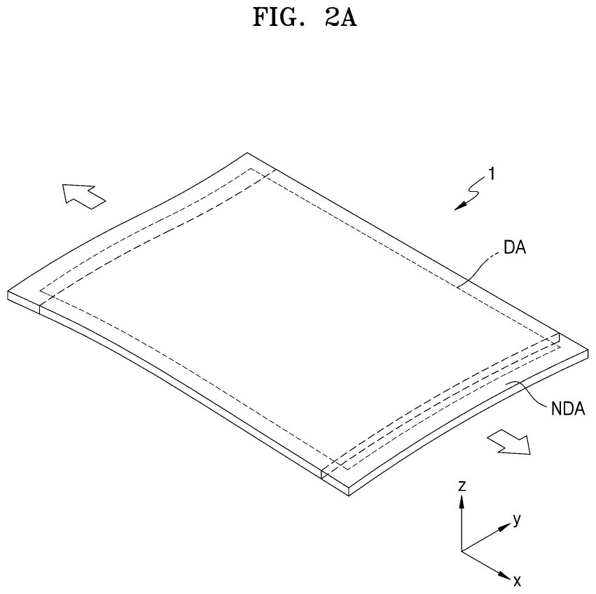

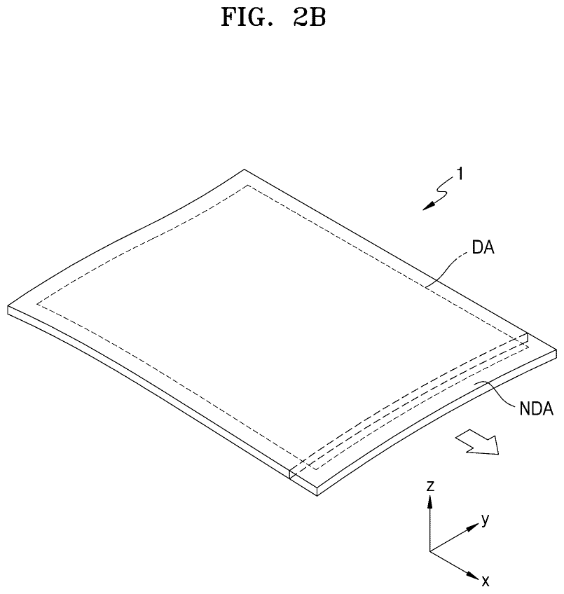

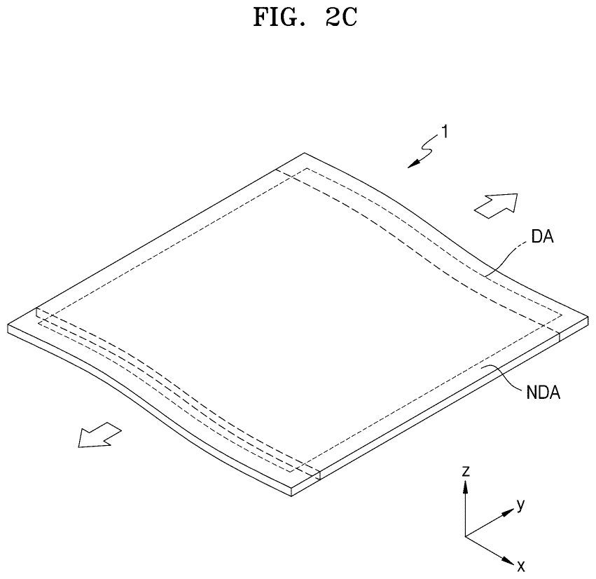

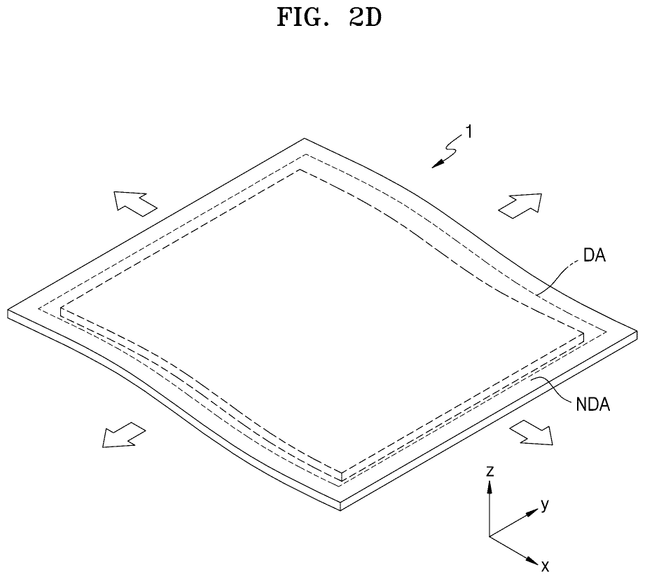

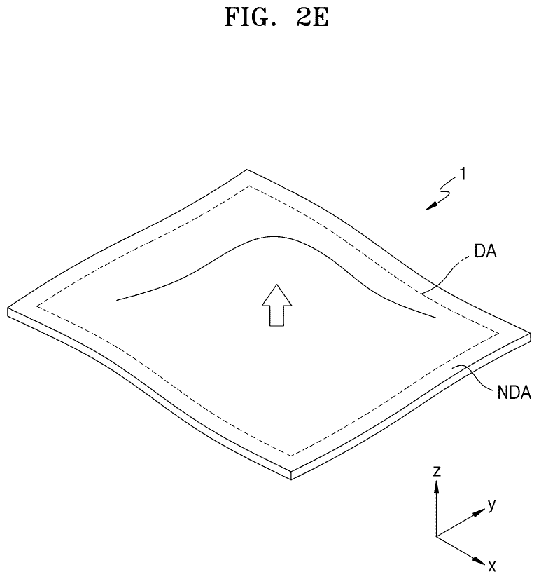

FIG. 1 is a schematic perspective view of a display device 1 according to an embodiment of the disclosure. FIGS. 2A and 2B are perspective views each illustrating a state in which the display device 1 of FIG. 1 is stretched in a first direction. FIG. 2C is a perspective view illustrating a state in which the display device 1 of FIG. 1 is stretched in a second direction. FIG. 2D is a perspective view illustrating a state in which the display device 1 of FIG. 1 is stretched in the first direction and the second direction. FIG. 2E is a perspective view illustrating a state in which the display device 1 of FIG. 1 is stretched in a third direction.

Referring to FIG. 1, the display device 1 may include a display area DA and a non-display area NDA. The display area DA may include a plurality of pixels. The display device 1 may provide an image by using light emitted by the plurality of pixels. The non-display area NDA may be disposed outside the display area DA. The non-display area NDA is an area in which the pixels are not disposed, and may entirely surround the display area DA.

The display device 1 may be stretched or shrunk in various directions. The display device 1 may be stretched in the first direction (e.g., an x direction and/or an-x direction) by an external force applied by an external object or a user. In an embodiment, as shown in FIGS. 2A and 2B, the display area DA and/or the non-display area NDA of the display device 1 may be stretched in the first direction (e.g., the x direction and/or the −x direction). For example, the display device 1 may be stretched in the x direction and the −x direction, as shown in FIG. 2A, or may be stretched in the x direction in a state in which one side of the display device 1 is fixed, as shown in FIG. 2B.

The display device 1 may be stretched in the second direction (e.g., a y direction and/or a −y direction) by an external force applied by an external object or a user. In an embodiment, as shown in FIG. 2C, the display area DA and/or the non-display area NDA of the display device 1 may be stretched in the y direction and the −y direction. In another embodiment, the display device 1 may be stretched in the y direction or the −y direction in a state in which one side of the display device 1 is fixed.

The display device 1 may be stretched in a plurality of directions, for example, the first direction (e.g., the x direction and/or the −x direction) and the second direction (e.g., the y direction and/or the −y direction), by an external force applied by an external object or a part of a human's body. As shown in FIG. 2D, the display area DA and/or the non-display area NDA of the display device 1 may be stretched in the ±x direction and the ±y direction.

The display device 1 may be stretched in the third direction (e.g., a z direction or a −z direction) by an external force applied by an external object or a part of a human's body. In an embodiment, FIG. 2E shows that a portion of the display device 1, for example, a partial area of the display area DA, protrudes in the z direction. In another embodiment, a portion of the display device 1, for example, a partial area of the display area DA, may protrude in the −z direction (or may be depressed in the z direction).

FIGS. 2A to 2E show that the display device 1 is stretched in the first direction, the second direction, and/or the third direction, but the disclosure is not limited thereto. In another embodiment, the display device 1 may be variously modified into irregular shapes, such as having two or more axes and being bent or twisted.

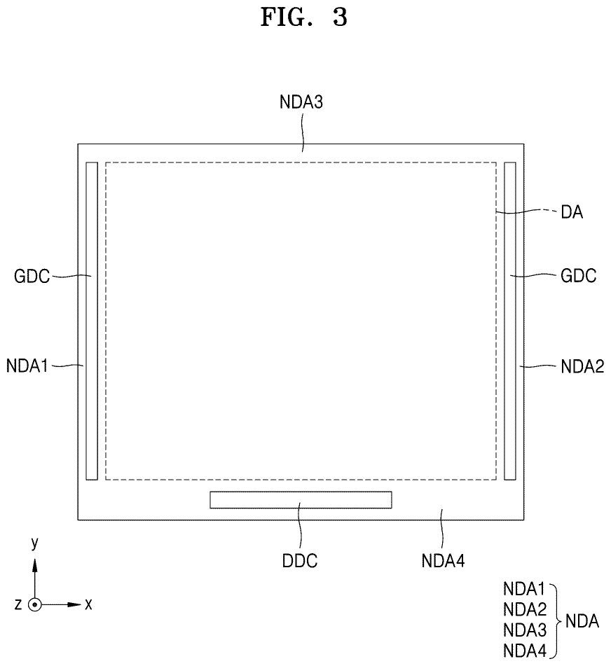

FIG. 3 is a schematic plan view of the display device 1 according to an embodiment of the disclosure. As used herein, the “plan view” is a view in a thickness direction (z direction) of the display device 1.

A plurality of pixels may be disposed in the display area DA of the display device 1. Each of the plurality of pixels may include sub-pixels emitting different colors of light. A light-emitting element corresponding to each sub-pixel may be disposed in the display area DA. A circuit configured to provide electrical signals to the light-emitting elements disposed in the display area DA and transistors electrically connected to the light-emitting elements may be positioned in the non-display area NDA surrounding the display area DA. Gate driving circuits GDC may be disposed in a first non-display area NDA1 and a second non-display area NDA2, respectively, where the first non-display area NDA1 and the second non-display area NDA2 are disposed on both sides of the display device 1 with the display area DA therebetween. A gate driving circuit GDC may include drivers configured to provide electrical signals to a gate electrode of each of the transistors electrically connected to the light-emitting elements. FIG. 3 shows that the gate driving circuit GDC is disposed in each of the first non-display area NDA1 and the second non-display area NDA2, but the disclosure is not limited thereto. In another embodiment, the gate driving circuit GDC may be disposed in any one of the first non-display area NDA1 and the second non-display area NDA2.

A data driving circuit DDC may be disposed in a third non-display area NDA3 and/or a fourth non-display area NDA4, which connects the first non-display area NDA1 to the second non-display area NDA2. In an embodiment, FIG. 3 shows that the data driving circuit DDC is disposed in the fourth non-display area NDA4. In another embodiment, the data driving circuit DDC may be disposed in each of the third non-display area NDA3 and the fourth non-display area NDA4.

FIG. 3 shows that the data driving circuit DDC is disposed in the fourth non-display area NDA4 of the display device 1, but the disclosure is not limited thereto. In another embodiment, the display device 1 may further include a flexible circuit board (not shown) electrically connected to a terminal portion (not shown) disposed in the fourth non-display area NDA4, and the data driving circuit DDC may be disposed on the flexible circuit board described above.

In some embodiments, the elongation of the non-display area NDA may be equal to or less than the elongation of the display area DA. In an embodiment, the non-display area NDA may have a different elongation for each area. For example, the first non-display area NDA1, the second non-display area NDA2, and the third non-display area NDA3 may have substantially the same elongation, but the elongation of the fourth non-display area NDA4 may be less than the elongation of each of the first non-display area NDA1, the second non-display area NDA2, and the third non-display area NDA3. In the disclosure, an elongation is a numerical value that represents a change in length (ΔL/L) by which the display device 1 may extend without physical damage to the display device 1 when an external force is applied to the display device 1. Herein, ΔL is a change in length of a display device, and L represents an initial length of the display device.

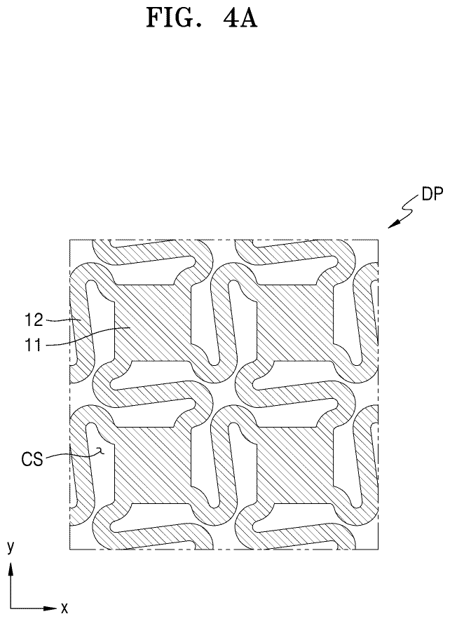

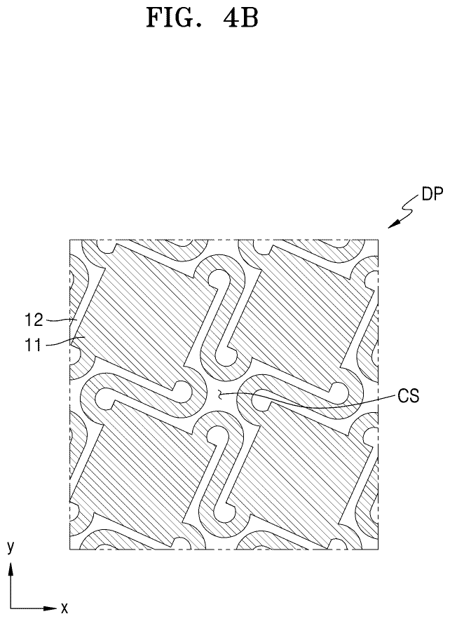

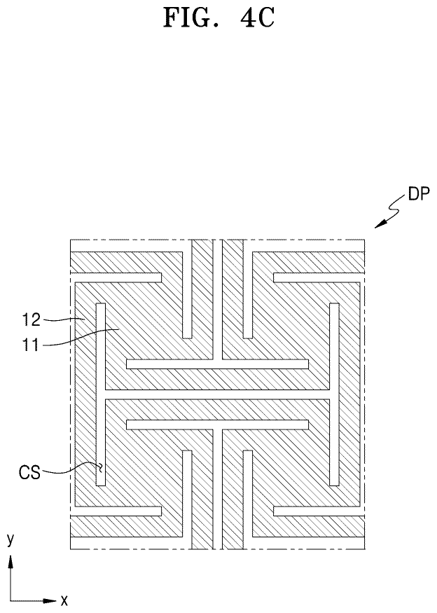

FIGS. 4A to 4C are plan views each schematically showing an excerpt of the display area DA of the display device 1 according to an embodiment of the disclosure.

Referring to FIG. 4A, the display device 1 may include, in the display area DA (refer to FIG. 1), a plurality of first island portions 11 spaced apart from each other in the first direction (e.g., the x direction or the −x direction) and the second direction (e.g., the y direction or the −y direction), and a plurality of first bridge portions 12 connecting adjacent first island portions 11 to each other.

Each first island portion 11 may be connected to the plurality of first bridge portions 12. For example, each first island portion 11 may be connected to four first bridge portions 12. Two first bridge portions 12 may be disposed on both sides of the first island portion 11 in the first direction (e.g., the x direction or the −x direction), and the remaining two first bridge portions 12 may be disposed on both sides of the first island portion 11 in the second direction (e.g., the y direction or the −y direction). In an embodiment, the four first bridge portions 12 may be connected to four sides of the first island portion 11, respectively. Each of the four first bridge portions 12 may be adjacent to each of corners of the first island portion 11.

The first bridge portions 12 may be disposed to be spaced apart from each other by opening portions CS positioned between the first bridge portions 12. A first bridge portion 12 may have a serpentine shape. For example, as shown in FIG. 4A, the first bridge portion 12 may have an approximate shape of ‘the letter S.’

Referring to FIG. 4B, the display device 1 may include, in the display area DA (refer to FIG. 1), the plurality of first island portions 11 spaced apart from each other in the first direction (e.g., the x direction or the −x direction) and the second direction (e.g., the y direction or the −y direction), and the plurality of first bridge portions 12 connecting adjacent first island portions 11 to each other. The first bridge portions 12 may be disposed to be spaced apart from each other by the opening portions CS positioned between the first bridge portions 12.

In an embodiment, at least one of the sides of the first island portion 11 may be obliquely tilted with respect to the first direction (e.g., the x direction or the −x direction) and/or the second direction (e.g., the y direction or the −y direction). FIG. 4B shows that all four sides of the first island portion 11 are obliquely tilted in a clockwise direction.

The first island portion 11 may be connected to the plurality of first bridge portions 12. For example, the first island portion 11 may be connected to four first bridge portions 12. Two first bridge portions 12 may be disposed on both sides of the first island portion 11 in the first direction (e.g., the x direction or the −x direction), and the remaining two first bridge portions 12 may be disposed on both sides of the first island portion 11 in the second direction (e.g., the y direction or the −y direction).

The first bridge portion 12 may have a serpentine shape. For example, as shown in FIG. 4B, the first bridge portion 12 may have an approximate shape of ‘the letter S.’

In an embodiment, the first bridge portion 12 may extend substantially parallel to a side of an adjacent first island portion 11, as shown in FIG. 4B. For example, the first bridge portion 12 may have two round portions connected to adjacent first island portions 11 and a straight-line portion connecting the round portions to each other. The straight-line portion of the first bridge portion 12 may extend substantially parallel to a side of an adjacent first island portion 11.

According to the arrangement of the first island portion 11 and/or the structure of the first bridge portion 12 as described above, an area of the opening portion CS shown in FIG. 4B may be less than an area of the opening portion CS shown in FIG. 4A, and accordingly, the display device 1 according to the embodiment shown in FIG. 4A may provide images with relatively high resolution.

Referring to FIG. 4C, the display device 1 may include, in the display area DA (refer to FIG. 1), the plurality of first island portions 11 spaced apart from each other in the first direction (e.g., the x direction or the −x direction) and the second direction (e.g., the y direction or the −y direction), and the plurality of first bridge portions 12 connecting adjacent first island portions 11 to each other.

Each first island portion 11 may be connected to the plurality of first bridge portions 12. For example, each first island portion 11 may be connected to four first bridge portions 12. Two first bridge portions 12 may be disposed on both sides of the first island portion 11 in the first direction (e.g., the x direction or the −x direction), and the remaining two first bridge portions 12 may be disposed on both sides of the first island portion 11 in the second direction (e.g., the y direction or the −y direction). In an embodiment, the four first bridge portions 12 may be connected to four sides of the first island portion 11, respectively. Each of the four first bridge portions 12 may be adjacent to each of corners of the first island portion 11.

The first bridge portions 12 may be spaced apart from each other by opening portions CS positioned between the first bridge portions 12. In an embodiment, an opening portion CS having an approximately H shape and an opening portion CS having an approximately I shape obtained by rotating the above-described H shape by 90 degrees may be alternately and repeatedly arranged in the each of the first direction (e.g., the x direction or the −x direction) and the second direction (e.g., the y direction or the −y direction). Opposite end portions of each first bridge portion 12 are connected to adjacent first island portions 11, respectively, but one side of each first bridge portion 12 may be spaced apart from one side of an adjacent first island portion 11 and/or one side of another first bridge portion 12 by the opening portion CS.

In an embodiment, the display device 1 may include, in the non-display area NDA (refer to FIG. 1), a plurality of second island portions spaced apart from each other in the first direction (e.g., the x direction or the −x direction) and the second direction (e.g., the y direction or the −y direction), and a plurality of second bridge portions connecting adjacent second island portions to each other. Accordingly, the non-display area NDA of the display device 1 may be stretched and recovered in various directions. A second island portion and a second bridge portion may have shapes identical to or similar to the first island portion 11 and the first bridge portion 12 of the display area DA, respectively, described above with reference to FIGS. 4A to 4C. In another embodiment of the disclosure, the second island portion and the second bridge portion of the non-display area NDA may have different shapes from that of the first island portion 11 and the first bridge portion 12 of the display area DA, respectively.

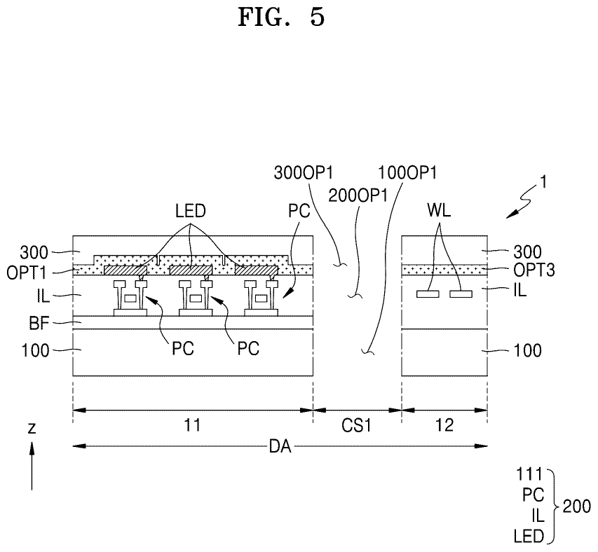

FIG. 5 is a schematic cross-sectional view of the first island portion 11 and the first bridge portion 12, which are disposed in the display area DA of the display device 1 according to an embodiment of the disclosure.

Referring to FIG. 5, the first island portion 11 and the first bridge portion 12, which are disposed in the display area DA, may be spaced apart from each other with a first opening portion CS1 between the first island portion 11 and the first bridge portion 12. The first island portion 11 may include light-emitting elements LED and a circuit electrically connected to the light-emitting elements LED and configured to drive the light-emitting elements LED, for example, a pixel driving circuit unit PC, and the first bridge portion 12 may include a line WL electrically connected to pixel driving circuit units PC disposed in adjacent first island portions 11, respectively.

When looking at the first island portion 11, a buffer layer BF including an inorganic insulating material may be disposed on a substrate 100, and the pixel driving circuit unit PC may be disposed on the buffer layer BF. An insulating layer IL including an inorganic insulating material and/or an organic insulating material may be disposed between the pixel driving circuit unit PC and a light-emitting element LED. The light-emitting element LED may be disposed on the insulating layer IL and may be electrically connected to a corresponding pixel driving circuit unit PC. The light-emitting elements LED may emit light of different colors or the same color. In an embodiment, the light-emitting elements LED may emit red, green, and blue light, respectively. In some embodiments, the light-emitting elements LED may emit white light. In another embodiment, the light-emitting elements LED may emit red, green, blue, and white light, respectively.

The substrate 100 may include a polymer resin, such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may be a single layer including the polymer resin described above. In another embodiment, the substrate 100 may have a multi-layered structure including a base layer including the polymer resin described above, and a barrier layer including an inorganic insulating material. The substrate 100 including the polymer resin may be flexible, rollable, or bendable.

In an embodiment, FIG. 5 shows three pixel driving circuit units PC disposed in each first island portion 11 and three light-emitting elements LED are connected to each of the pixel driving circuit units PC, but the disclosure is not limited thereto. In another embodiment, the number of each of the pixel driving circuit units PC and the light-emitting elements LED, which are disposed in the first island portion 11, may be one, two, three, or four or more.

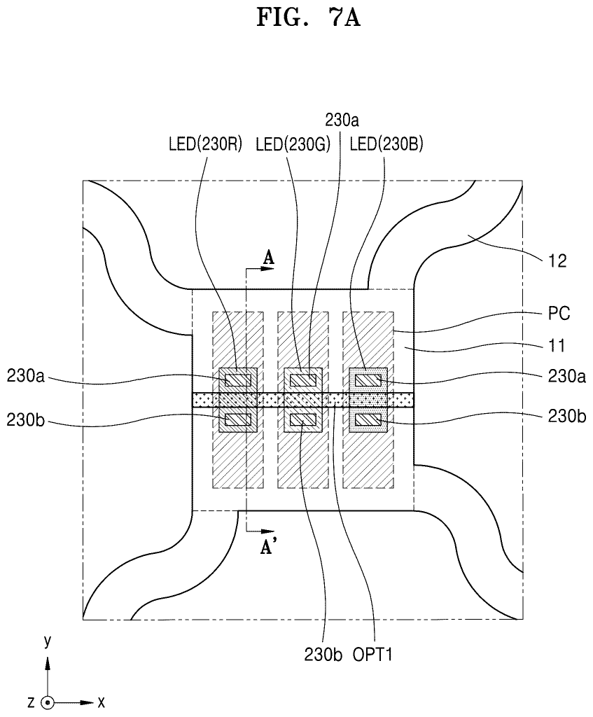

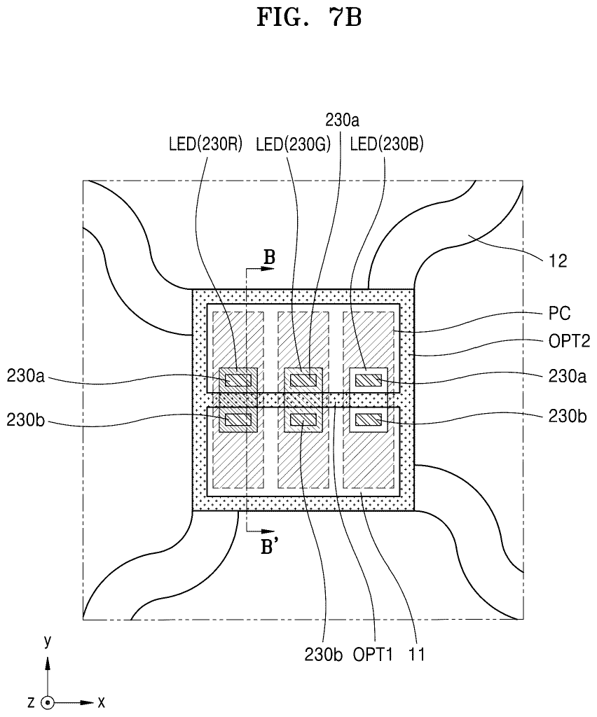

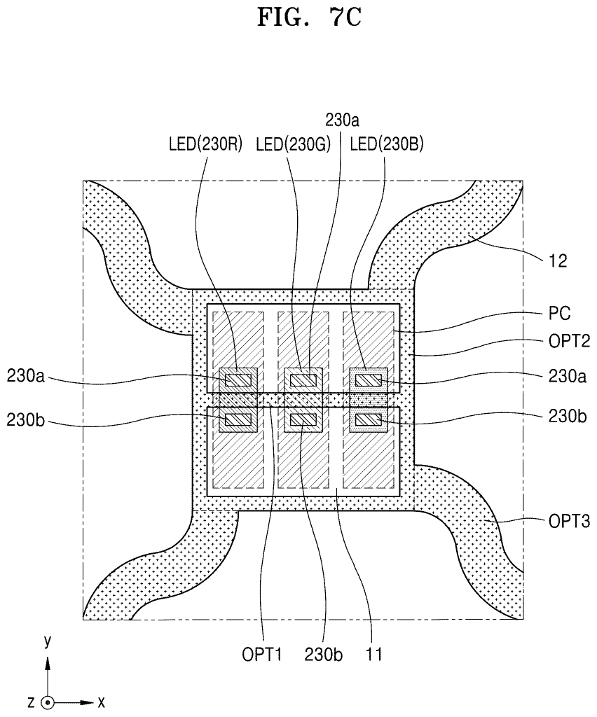

In the first island portion 11, a first organic pattern OPT1 may be positioned on the light-emitting elements LED. The first organic pattern OPT1 may be continuously disposed on the light-emitting elements LED in the first direction to support the light-emitting elements LEDs from the top. While FIG. 5 shows that the first organic pattern OPT1 completely covers upper surfaces of the light-emitting elements LED, the first organic pattern OPT1 according to an embodiment may be provided to only partially overlap the light-emitting elements LED in a plan view, as to be described below with reference to FIGS. 7A to 7C.

An encapsulation layer 300 may be disposed on the light-emitting element LED and may protect the light-emitting element LED from external force and/or moisture penetration. In particular, the encapsulation layer 300 may be disposed on the first organic pattern OPT1. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In some embodiments, the encapsulation layer 300 may include urethane epoxy acrylate. The encapsulation layer 300 may include a photosensitive material, for example, a material such as photoresist.

When looking at the first bridge portion 12, the insulating layer IL including an organic insulating material may be disposed on the substrate 100. When the display device 1 is stretched, the first bridge portion 12, which is relatively transformed, may not include a layer including an inorganic insulating material that is prone to cracks, unlike the first island portion 11.

In an embodiment, the substrate 100 corresponding to the first bridge portion 12 may have the same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a stacked structure different from that of the substrate 100 corresponding to the first island portion 11. In some embodiments, the substrate 100 corresponding to the first bridge portion 12 may have a multi-layered structure including a base layer including a polymer resin and a barrier layer including an inorganic insulating material, and the substrate 100 corresponding to the first bridge portion 12 may have a structure of a polymer resin layer without a layer including an inorganic insulating material.

As described above, lines WL of the first bridge portion 12 may be signal lines (e.g., gate lines, data lines, or the like) for providing electrical signals to transistors included in the pixel driving circuit unit PC of the first island portion 11, or may be voltage lines (e.g., driving voltage lines, initialization voltage lines, or the like) for providing voltages.

A third organic pattern OPT3 may be disposed on the insulating layer IL of the first bridge portion 12. The third organic pattern OPT3 is described in detail below with reference to FIG. 7C.

The encapsulation layer 300 may also be disposed in the first bridge portion 12. In another embodiment, the encapsulation layer 300 may not be present in the first bridge portion 12.

Referring to FIGS. 4A to 4C, and 5, the substrate 100 corresponding to the first island portion 11 and the substrate 100 corresponding to the first bridge portion 12 may be connected to each other. In other words, the plan views previously shown in FIGS. 4A to 4C may be substantially the same as the plan view of the substrate 100 of FIG. 5. That is, the substrate 100 may include an area corresponding to the first island portion 11, an area corresponding to the first bridge portion 12, and an opening 100OP1 having the same shape as the first opening portion CS1.

Similarly, the encapsulation layer 300 corresponding to the first island portion 11 and the encapsulation layer 300 corresponding to the first bridge portion 12 may be connected to each other. For example, the plan views previously shown in FIGS. 4A to 4C may be substantially the same as the plan view of the encapsulation layer 300. In other words, the encapsulation layer 300 may include an area corresponding to the first island portion 11, an area corresponding to the first bridge portion 12, and an opening 300OP1 having the same shape as the first opening portion CS1.

A circuit-light-emitting element layer 200 between the substrate 100 and the encapsulation layer 300 may include the buffer layer BF, the pixel driving circuit unit PC, the line WL, the insulating layer IL, and the light-emitting element LED. Similar to the substrate 100, the plan views previously shown in FIGS. 4A to 4C may be substantially the same as the plan view of the circuit-light-emitting element layer 200. In other words, the circuit-light-emitting element layer 200 may include an opening 200OP1 having the same shape as the first opening portion CS1.

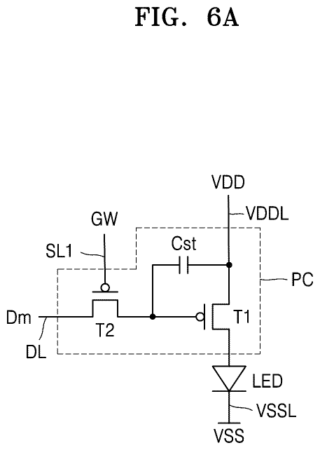

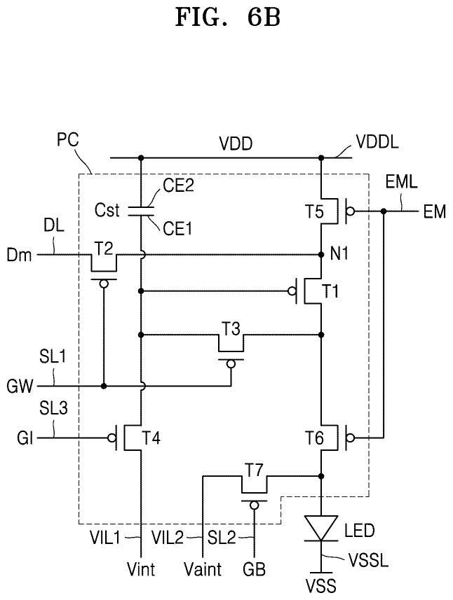

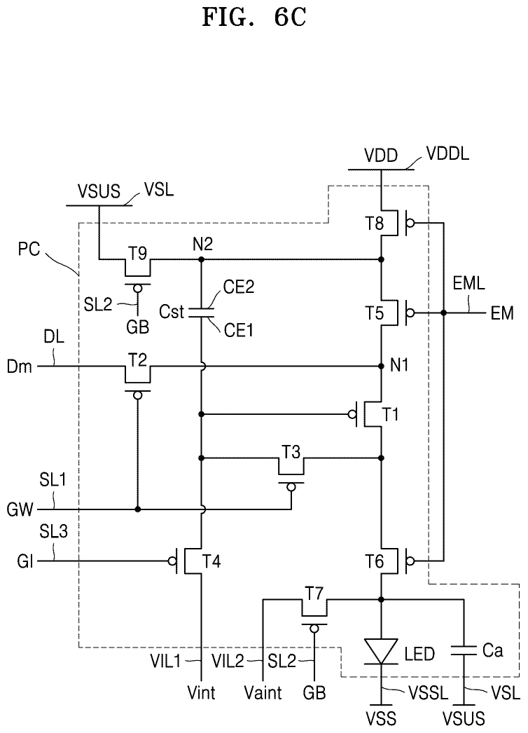

FIGS. 6A to 6C are equivalent circuit diagrams each illustrating a sub-pixel of the display device 1 according to an embodiment of the disclosure.

Referring to FIG. 6A, a light-emitting element LED corresponding to the sub-pixel may be electrically connected to a pixel driving circuit unit PC, and the pixel driving circuit unit PC may include a first transistor T1, a second transistor T2, and a storage capacitor Cst. The pixel driving circuit unit PC may be electrically connected to signal lines and voltage lines. The signal lines may include a gate line, such as a first scan line SL1, and a data line DL, and the voltage lines may include a first voltage line VDDL.

A second transistor T2 may be electrically connected to the first scan line SL1 and the data line DL. The first scan line SL1 may provide a first scan signal GW to a gate electrode of the second transistor T2. The second transistor T2 may be configured to transmit, to a first transistor T1, a data signal Dm input from the data line DL according to the first scan signal GW input from the first scan line SL1.

A storage capacitor Cst may be electrically connected to the second transistor T2 and the first voltage line VDDL, and may store a voltage corresponding to the difference between a voltage received from the second transistor T2 and a first power voltage VDD supplied by the first voltage line VDDL.

The first transistor T1 is a driving transistor, which may control a driving current flowing through the light-emitting element LED. The first transistor T1 may be connected to the first voltage line VDDL and the storage capacitor Cst. The first transistor T1 may control the driving current flowing through the light-emitting element LED from the first voltage line VDDL in accordance to a voltage value stored in the storage capacitor Cst. The light-emitting element LED may emit light having a certain brightness according to the driving current. A first electrode of the light-emitting element LED may be electrically connected to the first transistor T1, and a second electrode thereof may be electrically connected to a second voltage line VSSL providing a second power voltage VSS.

Although FIG. 6A illustrates that the pixel driving circuit unit PC includes two transistors and one storage capacitor, in another embodiment, the pixel driving circuit unit PC may include three or more transistors.

Referring to FIG. 6B, the pixel driving circuit unit PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit unit PC is electrically connected to signal lines and voltage lines. The signal lines may include gate lines, such as the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may be configured to transmit the first power voltage VDD to the first transistor T1. The first initialization voltage line VIL1 may be configured to transmit, to the pixel driving circuit unit PC, a first initialization voltage Vint initializing the first transistor T1. The second initialization voltage line VIL2 may be configured to transmit, to the pixel driving circuit unit PC, a second initialization voltage Vaint initializing the first electrode of the light-emitting element LED.

The first transistor T1 may be electrically connected to the first voltage line VDDL via the fifth transistor T5 and may be electrically connected to the light-emitting element LED via the sixth transistor T6. The first transistor T1 serves as a driving transistor and receives the data signal Dm in response to a switching operation of the second transistor T2 to supply a driving current to the light-emitting element LED.

The second transistor T2 is a data write transistor, which is electrically connected to the first scan line SL1 and the data line DL. The second transistor T2 is electrically connected to the first voltage line VDDL via the fifth transistor T5. The second transistor T2 is turned on in response to the first scan signal GW received through the first scan line SL1 and performs a switching operation of providing the data signal Dm provided with the data line DL to a first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1.

The fourth transistor T4 is a first initialization transistor, which is electrically connected to the third scan line SL3 and the first initialization voltage line VIL1. The fourth transistor T4 is turned on in response to a third scan signal GI received through the third scan line SL3 to provide the first initialization voltage Vint from the first initialization voltage line VIL1 to a gate electrode of the first transistor T1 to initialize a voltage of the gate electrode of the first transistor T1. The third scan signal GI may correspond to a first scan signal of another pixel driving circuit unit disposed in a previous row of the corresponding pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML and are simultaneously turned on in response to an emission control signal EM received through the emission control line EML to form a current path so that a driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 may be turned on in response to a second scan signal GB received through the second scan line SL2 to provide the second initialization voltage Vaint from the second initialization voltage line VIL2 to the first electrode of the light-emitting element LED to initialize the first electrode of the light-emitting element LED.

The storage capacitor Cst may include the first electrode CE1 and the second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to the difference between voltages of both ends of the first voltage line VDDL and the gate electrode of the first transistor T1.

Referring to FIG. 6C, the pixel driving circuit unit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit unit PC is electrically connected to signal lines and voltage lines. The signal lines may include gate lines, such as the first scan line SL1, the second scan line SL2, the third scan line SL3, and the emission control line EML, and the data line DL. The voltage lines may include the first and second initialization voltage lines VIL1 and VIL2, a maintenance voltage line VSL, and the first voltage line VDDL.

The first voltage line VDDL may be configured to transmit the first power voltage VDD to the first transistor T1. The first initialization voltage line VIL1 may be configured to transmit, to the pixel driving circuit unit PC, the first initialization voltage Vint initializing the first transistor T1. The second initialization voltage line VIL2 may be configured to transmit, to the pixel driving circuit unit PC, the second initialization voltage Vaint initializing the first electrode of the light-emitting element LED. The maintenance voltage line VSL may provide a maintenance voltage VSUS to a second node N2, for example, the second electrode CE2 of the storage capacitor Cst, during an initialization section and a data write section.

The first transistor T1 may be electrically connected to the first voltage line VDDL via the fifth transistor T5 and the eighth transistor T8, and may be electrically connected to the light-emitting element LED via the sixth transistor T6. The first transistor T1 may serve as a driving transistor and receive the data signal Dm in response to a switching operation of the second transistor T2 to supply a driving current to the light-emitting element LED.

The second transistor T2 is electrically connected to the first scan line SL1 and the data line DL, and is electrically connected to the first voltage line VDDL via the fifth transistor T5 and the eighth transistor T8. The second transistor T2 is turned on in response to the first scan signal GW received through the first scan line SL1 and performs a switching operation of transmitting the data signal Dm transmitted through the data line DL to the first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1, thereby compensating for a threshold voltage of the first transistor T1.

The fourth transistor T4 is electrically connected to the third scan line SL3 and the first initialization voltage line VIL1 and turned on in response to the third scan signal GI received through the third scan line SL3 to provide the first initialization voltage Vint from the first initialization voltage line VIL1 to the gate electrode of the first transistor T1 to initialize a voltage of the gate electrode of the first transistor T1. The third scan signal GI may correspond to a first scan signal of another pixel driving circuit unit disposed in a previous row of the corresponding pixel driving circuit unit PC.

The fifth transistor T5, the sixth transistor T6, and the eighth transistor T8 are electrically connected to the emission control line EML and simultaneously turned on in response to the emission control signal EM received through the emission control line EML to form a current path so that the driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 is turned on in response to the second scan signal GB received through the second scan line SL2 to provide the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the maintenance voltage line VSL. The ninth transistor T9 may be turned on in response to the second scan signal GB received through the second scan line SL2 to provide the maintenance voltage VSUS to the second node N2, for example, the second electrode CE2 of the storage capacitor Cst, during an initialization section and a data write section.

Each of the eighth transistor T8 and the ninth transistor T9 may be electrically connected to the second node N2, for example, the second electrode CE2 of the storage capacitor Cst. In some embodiments, the eighth transistor T8 may be turned off and the ninth transistor T9 may be turned on during the initialization section and the data write section, and the eighth transistor T8 may be turned on and the ninth transistor T9 may be turned off during an emission section. Because the maintenance voltage VSUS is transmitted to the second node N2 during the initialization section and the data write section, the brightness uniformity (for example, long-range uniformity (LRU)) of a display device according to a voltage drop of the first voltage line VDDL may be improved.

The storage capacitor Cst may include the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to a voltage difference between the first electrode of the light-emitting element LED and the maintenance voltage line VSL while the seventh transistor T7 and the ninth transistor T9 are turned on, so that a problem in which black brightness increases when the sixth transistor T6 is turned off may be prevented.

FIGS. 7A to 7C are schematic enlarged plan views of the first island portion 11 and the first bridge portion 12, which are disposed in the display area DA of the display device 1 according to an embodiment of the disclosure.

Referring to FIG. 7A, the display device 1 according to an embodiment of the disclosure may include the first bridge portions 12 each connected to the first island portion 11, and the first island portion 11 may include the first organic pattern OPT1.

The light-emitting elements LED corresponding to sub-pixels may be disposed on the first island portion 11. The light-emitting elements LED may be arranged in multiple numbers to be spaced apart from each other on one first island portion 11. FIGS. 7A to 7C show that three light-emitting elements LED are disposed on one first island portion 11. The light-emitting elements LED may emit the same color or may emit different colors, respectively. For example, the light-emitting elements LED may each include a first light-emitting diode 230R, a second light-emitting diode 230G, and a third light-emitting diode 230B. The first light-emitting diode 230R may emit red light, the second light-emitting diode 230G may emit green light, and the third light-emitting diode 230B may emit blue light.

The first organic pattern OPT1 may be disposed on the first to third light-emitting diodes 230R, 230G, and 230B. In other words, the first organic pattern OPT1 may be arranged to partially overlap the first to third light-emitting diodes 230R, 230G, and 230B in a plan view. The first organic pattern OPT1 may be continuously disposed on the first to third light-emitting diodes 230R, 230G, and 230B to extend in the first direction (e.g., the x direction and/or the −x direction). In a plan view, the first organic pattern OPT1 may have a shape of a bar or rectangle with the first direction (e.g., the x direction and/or the −x direction) as a longitudinal direction and the second direction (e.g., the y direction and/or the −y direction) as a width direction.

The first organic pattern OPT1 is provided as an integral body and is arranged to pass over the first to third light-emitting diodes 230R, 230G, and 230B from the top, thereby physically fixing the first to third light-emitting diodes 230R, 230G, and 230B. Accordingly, the first to third light-emitting diodes 230R, 230G, and 230B may be prevented from being detached in subsequent processes such as interlayer patterning and etching after transferring the first to third light-emitting diodes 230R, 230G, and 230B. Also, due to the characteristics of the display device 1 according to an embodiment of the disclosure, the first to third light-emitting diodes 230R, 230G, and 230B may be prevented from being detached due to stress propagation when performing an stretching (stretching and recovering) operation.

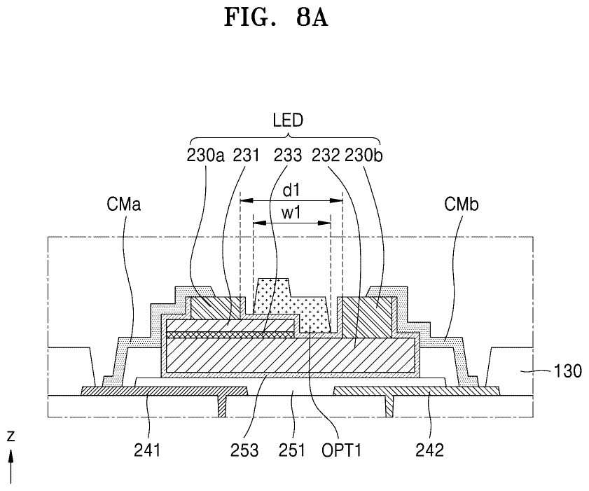

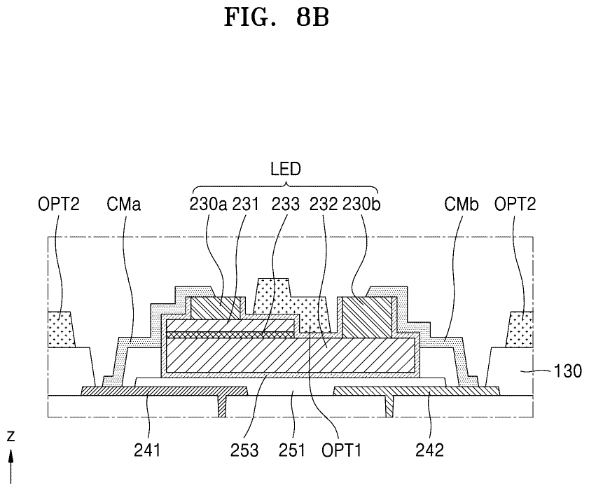

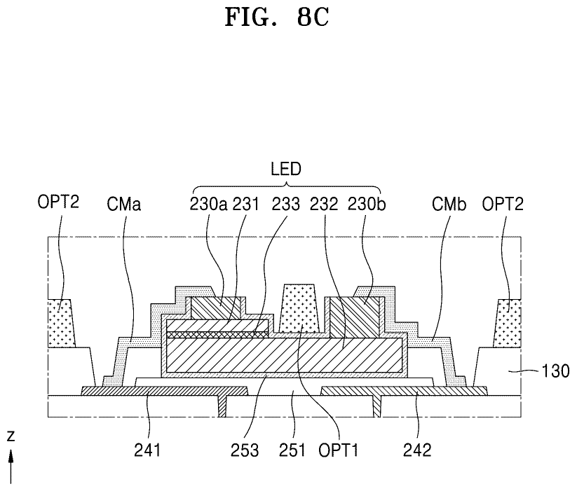

Each of the first to third light-emitting diodes 230R, 230G, and 230B may include a first electrode 230a and a second electrode 230b on an upper portion thereof. Each of the first to third light-emitting diodes 230R, 230G, and 230B may have a stacked structure as to be described below with reference to FIG. 8A, and the first electrode 230a and the second electrode 230b may be positioned on the uppermost portion of the stacked structure. The first electrode 230a and the second electrode 230b may be portions electrically connected to a pixel driving circuit unit PC positioned below the first electrode 230a and the second electrode 230b.

The first organic pattern OPT1 may be disposed not to overlap the first electrode 230a and the second electrode 230b in a plan view. In more detail, the first organic pattern OPT1 may be disposed to pass between the first electrode 230a and the second electrode 230b. First electrodes 230a of the first to third light-emitting diodes 230R, 230G, and 230B may be disposed in the same row, and in addition, second electrodes 230b of the first to third light-emitting diodes 230R, 230G, and 230B may be arranged in the same row while being spaced apart from the first electrodes 230a in the second direction (e.g., the y direction and/or the −y direction. The first organic pattern OPT1 may be disposed between the first electrode 230a and the second electrode 230b to extend in the first direction (e.g., the x direction and/or the −x direction).

The first organic pattern OPT1 may extend to an edge of the first island portion 11. That is, an end portion of the first organic pattern OPT1 may coincide with an end portion of the first island portion 11. In another embodiment, the end portion of the first organic pattern OPT1 may also be spaced apart from the end portion of the first island portion 11 by a certain distance.

The first organic pattern OPT1 may include an organic insulating material. For example, the first organic pattern OPT1 may include a material such as polyimide.

Referring to FIG. 7B, the first island portion 11 may further include the first organic pattern OPT1 and a second organic pattern OPT2.

The second organic pattern OPT2 may be disposed to surround the edges of the first island portion 11. In an embodiment, the second organic pattern OPT2 may have a frame shape surrounding the edges of the first island portion 11. The second organic pattern OPT2 may be provided to be in contact with the first organic pattern OPT1. Accordingly, because the second organic pattern OPT2 supports the first organic pattern OPT1 from the outside, the first organic pattern OPT1 may be prevented from being peeled off or lifted.

The first organic pattern OPT1 and the second organic pattern OPT2 may be provided as an integral body. The first organic pattern OPT1 and the second organic pattern OPT2 being provided as an integral body may mean that the first organic pattern OPT1 and the second organic pattern OPT2 may be formed through the same process.

The first organic pattern OPT1 and the second organic pattern OPT2 may include the same material. The first organic pattern OPT1 and the second organic pattern OPT2 may include an organic insulating material. For example, the first organic pattern OPT1 and the second organic pattern OPT2 may include a material such as polyimide.

The first organic pattern OPT1 and the second organic pattern OPT2 may also be formed through separate processes. At this time, the first organic pattern OPT1 and the second organic pattern OPT2 may include different materials. In an embodiment, because the first organic pattern OPT1 may pass over an upper portion of each of the first to third light-emitting diodes 230R, 230G, and 230B, the first organic pattern OPT1 may use a material with higher transmittance than the second organic pattern OPT2.

Referring to FIG. 7C, the first island portion 11 may include the first organic pattern OPT1 and the second organic pattern OPT2, and the first bridge portion 12 may further include the third organic pattern OPT3.

The third organic pattern OPT3 may be positioned on an upper portion of each of the first bridge portions 12. The third organic pattern OPT3 covers each of the first bridge portions 12 from the upper surfaces thereof, thereby alleviating the stress that the first bridge portions 12 receive when being stretched (stretched and recovered).

The third organic pattern OPT3 may be disposed to correspond to the entire surface of each of the first bridge portions 12. In other words, a width of the third organic pattern OPT3 may be equal to a width of the first bridge portion 12. The width of the first bridge portion 12 may mean the width of layers disposed below the third organic pattern OPT3 in the first bridge portion 12. Accordingly, the edge of the third organic pattern OPT3 may coincide with the edge of the first bridge portion 12. In other words, the width of the third organic pattern OPT3 may also be provided to be less than the width of the first bridge portion 12. In this case, the edge of the third organic pattern OPT3 may be provided to be spaced apart from the edge of the first bridge portion 12 by a certain distance.

The third organic pattern OPT3 may be provided to be integral with the first organic pattern OPT1 and the second organic pattern OPT2. That is, the first organic pattern OPT1, the second organic pattern OPT2, and the third organic pattern OPT3 may be connected into one layer. The first organic pattern OPT1, the second organic pattern OPT2, and the third organic pattern OPT3 being provided as an integral body may mean that the first organic pattern OPT1, the second organic pattern OPT2, and the third organic pattern OPT3 may be formed through the same process.

The third organic pattern OPT3 may include the same material as the material of the first organic pattern OPT1 and the second organic pattern OPT2. The third organic pattern OPT3 may include an organic insulating material. For example, the third organic pattern OPT3 may include a material such as polyimide.

The third organic pattern OPT3 may also be formed through a separate process from the first organic pattern OPT1 and the second organic pattern OPT2. At this time, the third organic pattern OPT3 may also include a different material from that of the first organic pattern OPT1 and the second organic pattern OPT2. In an embodiment, because the third organic pattern OPT3 is positioned in the first bridge portion 12, the third organic pattern OPT3 may include a material having a relatively greater elongation than that of the first organic pattern OPT1 and the second organic pattern OPT2, which are positioned in the first island portion 11.

FIGS. 8A to 8C are schematic cross-sectional views of light-emitting elements of the display device 1 according to an embodiment of the disclosure. FIG. 8A corresponds to a cross-section taken along a line A-A′ of FIG. 7A, and FIG. 8B corresponds to a cross-section taken along a line B-B′ of FIG. 7B.

Referring to FIG. 8A, the light-emitting element LED according to an embodiment of the disclosure may include an inorganic light-emitting diode including an inorganic material. The light-emitting element LED may include a first semiconductor layer 231, a second semiconductor layer 232, an intermediate layer 233 between the first semiconductor layer 231 and the second semiconductor layer 232, the first electrode 230a electrically connected to the first semiconductor layer 231, and the second electrode 230b electrically connected to the second semiconductor layer 232. The first electrode 230a and the second electrode 230b of the light-emitting element LED may be electrically connected to a first electrode pad 241 and a second electrode pad 242, respectively, which are disposed on the same layer. The second electrode pad 242 may be a portion of the second voltage line VSSL (refer to FIG. 6A) or a conductive layer electrically connected to the second voltage line VSSL (refer to FIG. 6A).

In an embodiment, the first semiconductor layer 231 may include a p-type semiconductor layer. The p-type semiconductor layer is a semiconductor material with a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, or the like, and may be doped with a p-type dopant such as Mg, Zn, Ca, Sr, Ba, or the like.

The second semiconductor layer 232 may include, for example, an n-type semiconductor layer. The n-type semiconductor layer is a semiconductor material having a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, or the like, and may be doped with an n-type dopant such as Si, Ge, Sn, or the like.

The intermediate layer 233 is a region where electrons and holes are recombined, as the electrons and holes are recombined, the intermediate layer 233 may transition to a low energy level and generate light having a corresponding wavelength. For example, the intermediate layer 233 may be formed by including a semiconductor material having a composition formula of InₓAl_{y}Ga_{1-x-y}N (0≤x≤1, 0≤y≤1, 0≤x+y≤1), and may be formed as a single-quantum well structure or a multi-quantum well (MQW) structure. In addition, the intermediate layer 233 may also include a quantum wire structure or a quantum dot structure.

FIG. 8A illustrates that the first semiconductor layer 231 includes a p-type semiconductor layer, and the second semiconductor layer 232 includes an n-type semiconductor layer, but the disclosure is not limited thereto. In another embodiment, the first semiconductor layer 231 may include an n-type semiconductor layer, and the second semiconductor layer 232 may include a p-type semiconductor layer.

FIG. 8A illustrates that the first electrode pad 241 and the second electrode pad 242 are disposed on the same layer, but the disclosure is not limited thereto. The first electrode pad 241 and the second electrode pad 242 may be disposed on different layers.

The first electrode 230a and the second electrode 230b of the light-emitting element LED may face the same direction and may face the +z direction. The first electrode 230a and the second electrode 230b may be disposed on a stacked structure of the first semiconductor layer 231, the intermediate layer 233, and the second semiconductor layer 232. In a plan view, the first electrode 230a and the second electrode 230b may have a structure disposed adjacent to each other but spaced apart from each other by a certain distance, that is, a lateral diode structure. Such a lateral diode structure does not use pressure during transfer, and thus physical damage to underlying layers or circuit structures may be prevented.

The light-emitting element LED may be attached to the first electrode pad 241 and the second electrode pad 242 by using an adhesive layer 251. In another embodiment, the adhesive layer 251 may also be omitted in some cases.

In an embodiment, a protective film 253 may be disposed outside the light-emitting element LED. The protective film 253 may include an organic insulating material and/or an inorganic insulating material. The protective film 253 may include, for example, polyimide. In another embodiment, the protective film 253 may also be omitted in some cases.

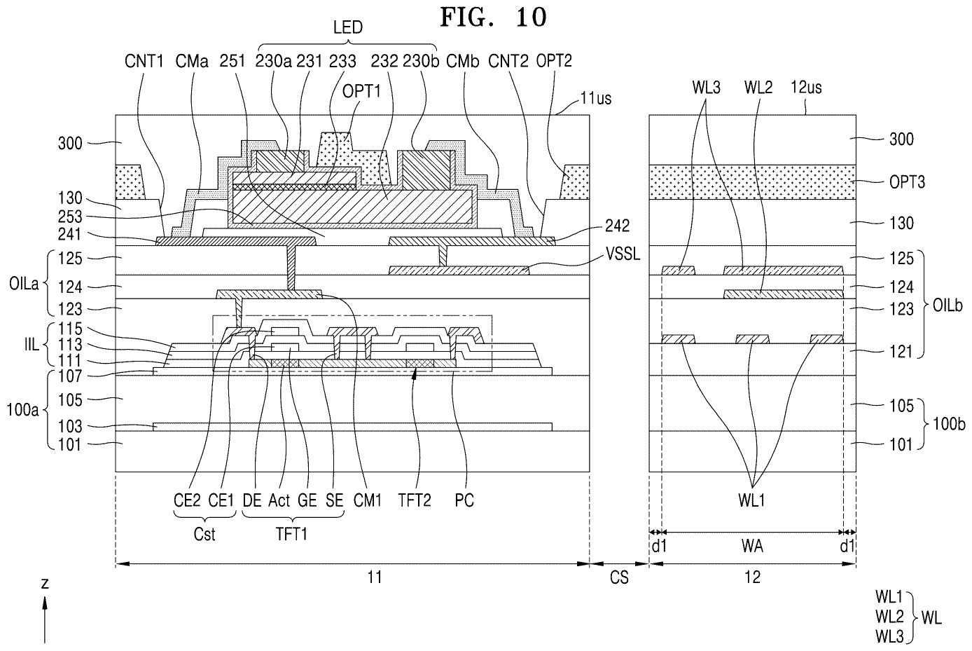

An organic insulating film 130 may be disposed on the first electrode pad 241 and the second electrode pad 242. The organic insulating film 130 may define a first contact hole CNT1 and a second contact hole CNT2 therein (See FIG. 10) exposing at least a portion of the first electrode pad 241 and the second electrode pad 242, respectively. The organic insulating film 130 may include, for example, polyimide. At least a portion of the light-emitting element LED may have an embedded structure surrounded by the organic insulating film 130. FIG. 8A illustrates that at least a portion of the stacked structure including the first semiconductor layer 231, the second semiconductor layer 232, and the intermediate layer 233 is embedded in the organic insulating film 130. In this case, the first electrode 230a and the second electrode 230b of the light-emitting element LED may also protrude in the +z direction more than an upper surface of the organic insulating film 130.

The first electrode pad 241 may be electrically connected to the first electrode 230a of the light-emitting element LED through a first contact electrode CMa, and the second electrode pad 242 may be electrically connected to the second electrode 230b of the light-emitting element LED through a second contact electrode CMb. One end portion of the first contact electrode CMa may be connected to the first electrode pad 241 through the first contact hole CNT1 exposing at least a portion of the first electrode pad 241, and another end portion thereof may be connected to the first electrode 230a. Also, one end portion of the second contact electrode CMb may be connected to the second electrode pad 242 through the second contact hole CNT2 exposing at least a portion of the second electrode pad 242, and another end portion thereof may be connected to the second electrode 230b.

The first contact electrode CMa and the second contact electrode CMb may each include a conductive material including molybdenum (Mo), aluminum (Al), copper (Cu), titanium (Ti), or the like, and may include a multi-layer or a single layer, each including the above material. Alternatively, the first contact electrode CMa and the second contact electrode CMb may each include a transparent conductive material. For example, the first contact electrode CMa and the second contact electrode CMb may each include a transparent conducting oxide (TCO), such as indium tin oxide (ITO), indium zinc oxide (IZO), zinc oxide (ZnO), indium oxide (In₂O₃), indium gallium oxide (IGO), or aluminum zinc oxide (AZO).

The first organic pattern OPT1 may be disposed between the first electrode 230a and the second electrode 230b. FIG. 8A illustrates that the first organic pattern OPT1 is positioned on the protective film 253. In another embodiment, when the protective film 253 is omitted, the first organic pattern OPT1 may also be disposed directly on the first semiconductor layer 231 and/or the second semiconductor layer 232. Alternatively, in another embodiment, the organic insulating film 130 may cover an upper portion of the first semiconductor layer 231 and/or the second semiconductor layer 232, and the first organic pattern OPT1 may be disposed on the organic insulating film 130.

As shown in FIG. 8A, the first organic pattern OPT1 may be disposed across a step-difference formed by the first semiconductor layer 231 and the intermediate layer 233. Alternatively, as shown in FIG. 8C, the first organic pattern OPT1 may also be disposed on the second semiconductor layer 232 (or the first semiconductor layer 231) having a flat upper surface.

A width w1 of the first organic pattern OPT1 may be equal to or less than a distance d1 between the first electrode 230a and the second electrode 230b. The width w1 is measured in the same direction as the distance d1. Accordingly, the first organic pattern OPT1 may overlap a portion of the light-emitting element LED in a plan view.

As a comparative example, it may be assumed that a first organic pattern overlaps the entire light-emitting element LED instead of overlapping a portion of the light-emitting element LED in a plan view. However, in this case, a problem may occur in which light efficiency emitted from the light-emitting element LED is reduced due to the light transmittance and refractive index of a material layer forming the first organic pattern. Accordingly, in the display device 1 according to an embodiment of the disclosure, the first organic pattern OPT1 may be provided to overlap only a portion of the light-emitting element LED in a plan view to reduce reduction in light transmittance of the light-emitting element LED while supporting the light-emitting elements LED from above.

Referring to FIG. 8B, the second organic pattern OPT2 may be positioned on the organic insulating film 130. The second organic pattern OPT2 may be disposed to surround the edges of the first island portion 11. As shown in FIG. 7B, the second organic pattern OPT2 may have a frame shape surrounding the edges of the first island portion 11. The second organic pattern OPT2 may be provided to be in contact with the first organic pattern OPT1. Accordingly, because the second organic pattern OPT2 supports the first organic pattern OPT1 from the outside, the first organic pattern OPT1 may be prevented from being peeled off or lifted.

The second organic pattern OPT2 may be disposed to be spaced apart from the first contact hole CNT1 and the second contact hole CNT2, which are defined in the organic insulating film 130, by a certain distance. An end portion of the second organic pattern OPT2 may coincide with the edge of the first island portion 11. This may be understood as a reason that the second organic pattern OPT2 is also patterned during patterning to form the first island portion 11 and the first bridge portion 12.

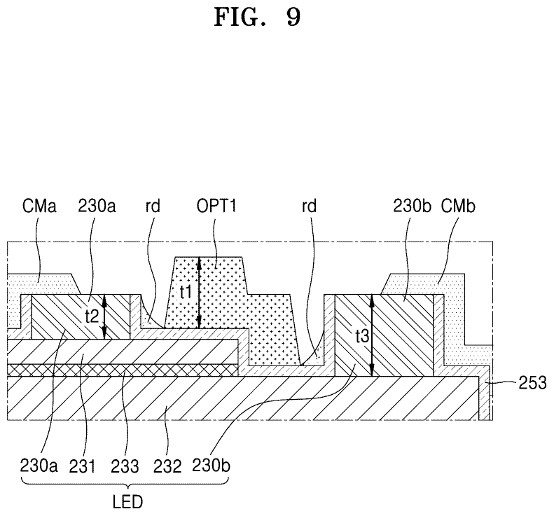

FIG. 9 is an enlarged cross-sectional view schematically illustrating a portion of the display device 1 according to an embodiment of the disclosure.

Referring to FIG. 9, in an embodiment, a residue layer rd may be positioned between the first electrode 230a and the second electrode 230b. The residue layer rd may be positioned on a stepped portion of the first electrode 230a on the first semiconductor layer 231 and/or a stepped portion of the second electrode 230b on the second semiconductor layer 232. FIG. 9 illustrates that the residue layer rd is positioned on the protective film 253 disposed outside the light-emitting element LED, but when the protective film 253 is omitted, the residue layer rd may be in contact with a portion of an upper surface of the first semiconductor layer 231 and a portion of a side surface of the first electrode 230a and may be in contact with a portion of an upper surface of the second semiconductor layer 232 and a portion of a side surface of the second electrode 230b.

In an embodiment, the residue layer rd may be formed in a patterning process for forming the first island portion 11 and the first bridge portion 12, that is, a hard mask process. The first electrode 230a and the second electrode 230b may have a certain thickness, and a step-difference caused by the certain thickness may result in residue that is not completely removed during an etching process. Accordingly, the residue layer rd may include the same material as a material used in the hard mask process. The residue layer rd may include a TCO, such as ITO, IZO, ZnO, In₂O₃, IGO, or AZO.

As the first organic pattern OPT1 is disposed between the first electrode 230a and the second electrode 230b, a short circuit may be prevented from occurring between the first electrode 230a and the second electrode 230b due to the residue of the residue layer rd. In some embodiments, a thickness t1 of the first organic pattern OPT1 may be greater than each of thicknesses t2 and t3 of the first electrode 230a and the second electrode 230b. In some embodiments, a top surface of the first organic pattern OPT1 may be positioned higher from the substrate 100 (refer to FIG. 5) than the top surface of each of the first electrode 230a and the second electrode 230b.

FIG. 10 is a schematic cross-sectional view of a portion of a display area of the display device 1 according to an embodiment of the disclosure.

Referring to FIG. 10, the first island portion 11 and the first bridge portion 12 of the display device 1 according to an embodiment of the disclosure may be spaced apart from each other with the opening portion CS therebetween. The first island portion 11 may include the light-emitting element LED and a pixel circuit PC electrically connected to the light-emitting element LED, and the first bridge portion 12 may include lines WL electrically connected to the pixel circuit PC disposed in the first island portion 11.

The substrate 100 may include an island area 100a corresponding to the first island portion 11 and a bridge area 100b corresponding to the first bridge portion 12. In an embodiment, the substrate 100 may have a multi-layered structure including base layers 101 and 105 each including a polymer resin and barrier layers 103 and 107 each including an inorganic insulating material. For example, the substrate 100 may include a first base layer 101, a second base layer 105 on the first base layer 101, a first barrier layer 103 between the first base layer 101 and the second base layer 105, and a second barrier layer 107 on the second base layer 105. The first base layer 101 and the second base layer 105 may each include a polymer resin, and the first barrier layer 103 and the second barrier layer 107 may each include an inorganic insulating material. The first barrier layer 103 and the second barrier layer 107 may each have an isolated shape disposed in the first island portion 11. That is, in a plan view, the first barrier layer 103 and the second barrier layer 107 may not overlap the bridge area 100b.

When looking at the first island portion 11 first, the pixel circuit PC may be disposed on the second barrier layer 107. The pixel circuit PC may include a first thin-film transistor TFT1, a second thin-film transistor TFT2, and a storage capacitor Cst. Each of the first thin-film transistor TFT1 and the second thin-film transistor TFT2 may include a semiconductor layer Act, a gate electrode GE, a source electrode SE, and a drain electrode DE. In an embodiment, the first thin-film transistor TFT1 may be a driving transistor, and the second thin-film transistor TFT2 may be a switching transistor. FIG. 10 illustrates that each of the first thin-film transistor TFT1 and the second thin-film transistor TFT2 is a top-gate type in which the gate electrode GE is disposed on the semiconductor layer Act with a gate insulating layer 111 therebetween, but according to another embodiment, each of the first thin-film transistor TFT1 and the second thin-film transistor TFT2 may be a bottom-gate type.

Inorganic insulating layers forming an inorganic insulating stack IIL may be disposed between the semiconductor layer Act and conductive layers forming the pixel circuit PC. The inorganic insulating stack IIL may include the gate insulating layer 111, a first interlayer insulating layer 113, and a second interlayer insulating layer 115. Each of the gate insulating layer 111, the first interlayer insulating layer 113, and the second interlayer insulating layer 115 may include an inorganic insulating material, such as silicon oxide, silicon nitride, silicon oxynitride, aluminum oxide, titanium oxide, or the like, and may include a single layer or a multi-layer, each including the material described above.

The semiconductor layer Act may include polysilicon. Alternatively, the semiconductor layer Act may include amorphous silicon, an oxide semiconductor, an organic semiconductor, or the like. The gate electrode GE may include a metal thin film including a low-resistance metal material. The gate electrode GE may include a conductive material including Mo, Al, Cu, Ti, or the like, and may include a multi-layer or a single layer, each including the material stated above. For example, the gate electrode GE may include a metal thin film including a triple layer of a Ti/Al/Ti structure. The gate insulating layer 111 may be disposed between the semiconductor layer Act and the gate electrode GE.

The source electrode SE and the drain electrode DE may be positioned on the same layer, for example, the second interlayer insulating layer 115, and may include the same material. The source electrode SE and the drain electrode DE may each include a metal thin film including a low-resistance metal material. The source electrode SE and the drain electrode DE may each include a conductive material including Mo, Al, Cu, Ti, or the like, and may include a multi-layer or a single layer, each including the above material. For example, similar to the gate electrode GE, the source electrode SE and the drain electrode DE may each include a metal thin film including a triple layer of a Ti/Al/Ti structure.

The storage capacitor Cst may include the first electrode CE1 and the second electrode CE2, which overlap each other with the first interlayer insulating layer 113 therebetween. The storage capacitor Cst may overlap the first thin-film transistor TFT1 in a plan view. In this regard, FIG. 10 shows that the gate electrode GE of the first thin-film transistor TFT1 is integrally provided with the first electrode CE1 of the storage capacitor Cst. In another embodiment, the storage capacitor Cst may not overlap a first thin-film transistor TFT1 in a plan view. The storage capacitor Cst may be covered with the second interlayer insulating layer 115.

The second electrode CE2 of the storage capacitor Cst may include a conductive material and may include a multi-layer or a single layer. The second electrode CE2 may include a metal thin film including a low-resistance metal material. The second electrode CE2 may include a conductive material including Mo, Al, Cu, Ti, or the like, and may include a multi-layer or a single layer, each including the above material. For example, the second electrode CE2 may include a metal thin film including a triple layer of a Ti/Al/Ti structure.

A first organic insulating stack OILa may be disposed on the inorganic insulating stack IIL. The first organic insulating stack OILa may include a first organic insulating layer 123, a second organic insulating layer 124, and a third organic insulating layer 125. The first organic insulating layer 123, the second organic insulating layer 124, and the third organic insulating layer 125 may each include an organic insulating material, and may each include a multi-layer or a single layer.

The first organic insulating layer 123 may be disposed on the source electrode SE and the drain electrode DE. A third contact electrode CM1 may be disposed on the first organic insulating layer 123. The third contact electrode CM1 may be electrically connected to the drain electrode DE of the first thin-film transistor TFT1 through a contact hole penetrating the first organic insulating layer 123. The third contact electrode CM1 may include a conductive material including Mo, Al, Cu, Ti, or the like, and may include a multi-layer or a single layer, each including the above material.

The second organic insulating layer 124 may be disposed on the third contact electrode CM1, and the second voltage line VSSL may be disposed on the second organic insulating layer 124. The second voltage line VSSL may be electrically connected to a second electrode of the light-emitting element LED to supply the second power voltage VSS. The second voltage line VSSL may include a conductive material including Mo, Al, Cu, Ti, or the like, and may include a multi-layer or a single layer, each including the above material.

The third organic insulating layer 125 may be disposed on the second voltage line VSSL, and the first electrode pad 241 and the second electrode pad 242 may be disposed on the third organic insulating layer 125. The first electrode pad 241 may be electrically connected to the third contact electrode CM1 through contact holes penetrating the second organic insulating layer 124 and the third organic insulating layer 125. The second electrode pad 242 may be electrically connected to the second voltage line VSSL through a contact hole penetrating the third organic insulating layer 125.

The light-emitting element LED may be disposed on the first electrode pad 241 and the second electrode pad 242. The structure of the light-emitting element LED is the same as that described above with reference to FIG. 8A. The light-emitting element LED may be attached to the first electrode pad 241 and the second electrode pad 242 by using the adhesive layer 251.

The organic insulating film 130 may be disposed on the first electrode pad 241 and the second electrode pad 242. The organic insulating film 130 may cover the first electrode pad 241 and the second electrode pad 242 and may have the first contact hole CNT1 and the second contact hole CNT2 exposing at least a portion of the first electrode pad 241 and the second electrode pad 242, respectively. At least a portion of the light-emitting element LED may be disposed to be embedded in the organic insulating film 130.

The first electrode 230a and the second electrode 230b of the light-emitting element LED may protrude above the upper surface of the organic insulating film 130. In other words, the first electrode 230a and the second electrode 230b may be disposed to protrude in the +z direction. In a plan view, the first electrode 230a and the second electrode 230b may have a structure disposed adjacent to each other but spaced apart from each other by a certain distance, that is, a lateral diode structure. Such a lateral diode structure does not use pressure during transfer, and thus physical damage to underlying layers or circuit structures may be prevented.

The first electrode 230a of the light-emitting element LED may be electrically connected to the pixel circuit PC through the first contact electrode CMa, the first electrode pad 241, and the third contact electrode CM1. The second electrode 230b of the light-emitting element LED may be electrically connected to the second voltage line VSSL through the second contact electrode CMb and the second electrode pad 242.

The first organic pattern OPT1 may be disposed between the first electrode 230a and the second electrode 230b. As shown in FIG. 7C or the like, the first organic pattern OPT1 may be disposed to continuously pass over the upper portions of the first to third light-emitting diodes 230R, 230G, and 230B. Accordingly, the first to third light-emitting diodes 230R, 230G, and 230B may be prevented from being detached in subsequent processes such as interlayer patterning and etching after transferring the first to third light-emitting diodes 230R, 230G, and 230B. Also, due to the characteristics of the display device 1 according to an embodiment of the disclosure, the first to third light-emitting diodes 230R, 230G, and 230B may be prevented from being detached due to stress propagation when performing an stretching (stretching and recovering) operation.

The second organic pattern OPT2 may be disposed on the organic insulating film 130 to surround the edges of the first island portion 11. The second organic pattern OPT2 may be disposed to be spaced apart from the first contact hole CNT1 and the second contact hole CNT2 by a certain distance. As shown in FIG. 7C or the like, the second organic pattern OPT2 may be connected to the first organic pattern OPT1 or may be integrally provided with the first organic pattern OPT1.

In some embodiments, the encapsulation layer 300 may be disposed on the first organic pattern OPT1 and the second organic pattern OPT2. The encapsulation layer 300 may be disposed to cover the entire surfaces of the first organic pattern OPT1, the second organic pattern OPT2, and the light-emitting element LED. The encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin.

The first island portion 11 of the display device 1 may show a stacked structure from the island area 100a of the substrate 100 to the encapsulation layer 300 disposed on the island area 100a. In the disclosure, an upper surface means a surface on which an image is displayed in the display device 1, that is, a surface facing the substrate 100. In FIG. 10, the upper surface of the first island portion 11 may be an upper surface of the encapsulation layer 300.

When looking at the first bridge portion 12, only base layers may be disposed on the bridge area 100b of the substrate 100. For example, only the first base layer 101 and the second base layer 105 may be disposed in the bridge area 100b, and in a plan view, the first barrier layer 103 and the second barrier layer 107 may be spaced apart from the bridge area 100b and may not overlap the bridge area 100b in a plan view.

A second organic insulating stack OILb may be disposed on the bridge area 100b of the substrate 100. The second organic insulating stack OILb may include the first organic insulating layer 123, the second organic insulating layer 124, the third organic insulating layer 125, and a fourth organic layer 121. The first organic insulating layer 123, the second organic insulating layer 124, and the third organic insulating layer 125 of the second organic insulating stack OILb may be formed through the same process of the first organic insulating layer 123, the second organic insulating layer 124, and the third organic insulating layer 125 of the first organic insulating stack OILa. Because the bridge area 100b does not include the inorganic insulating stack IIL, the second organic insulating stack OILb may further include the fourth organic layer 121 to align with the upper surface and level of the inorganic insulating stack IIL. In an embodiment, the first island portion 11 may further include the fourth organic layer 121, and the fourth organic layer 121 may be disposed to cover a side surface of the inorganic insulating stack IIL having an isolated shape. The fourth organic layer 121 may include an organic insulating material, and may include a multi-layer or a single layer.

First lines WL1 may be disposed on the fourth organic layer 121, a second line WL2 may be disposed on the first organic insulating layer 123, and third lines WL3 may be disposed on the second organic insulating layer 124. As described above, each of the first lines WL1, the second line WL2, and the third lines WL3 may be a signal line (e.g., a gate line, a data line, or the like) for providing electrical signals to a transistor included in the pixel circuit PC of the first island portion 11 or a voltage line (e.g., a power voltage line, an initialization voltage line, or the like) for providing voltages. The lines WL may include a conductive material including Mo, Al, Cu, Ti, or the like, and may include a multi-layer or a single layer, each including the above material.

The lines WL may be disposed in a line area WA. A width of the line area WA may be less than a width of the bridge area 100b. For example, an edge of the line area WA may be spaced inwardly apart from an edge of the bridge area 100b. FIG. 10 illustrates that the edge of the line area WA is spaced inwardly apart from both edges of the bridge area 100b by a first distance d1.

The encapsulation layer 300 may be disposed on the second organic insulating stack OILb. The encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin.

The first bridge portion 12 of the display device 1 may show a stacked structure from the bridge area 100b of the substrate 100 to the encapsulation layer 300 disposed on the bridge area 100b. An upper surface of the first bridge portion 12 may be the upper surface of the encapsulation layer 300.

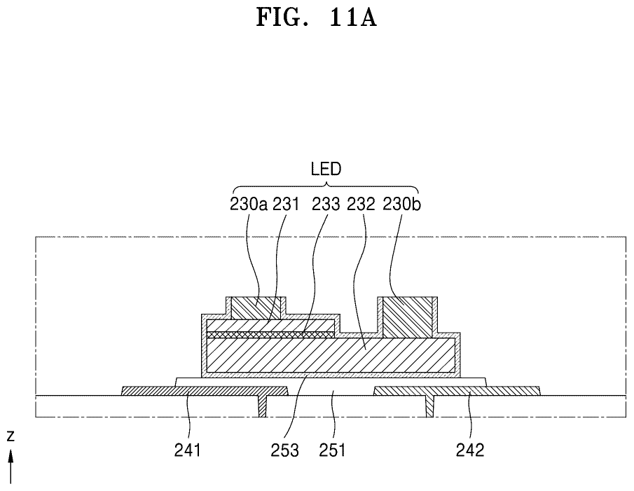

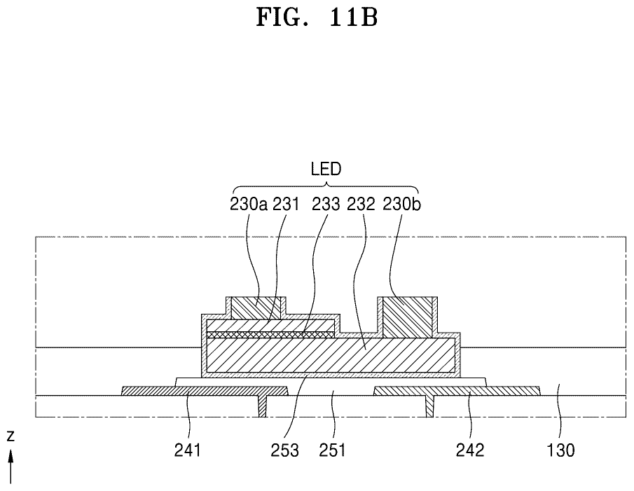

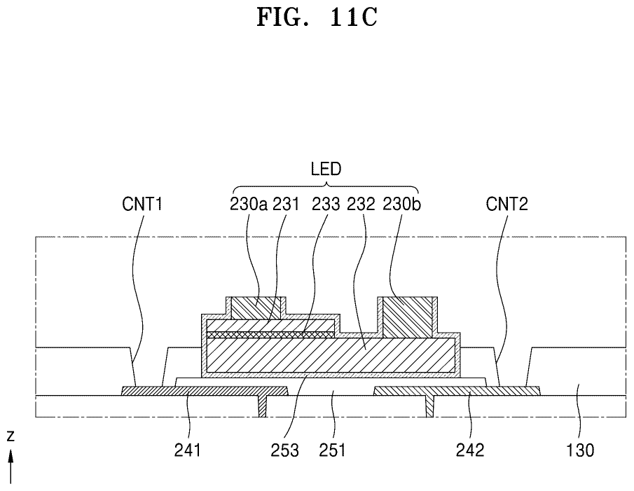

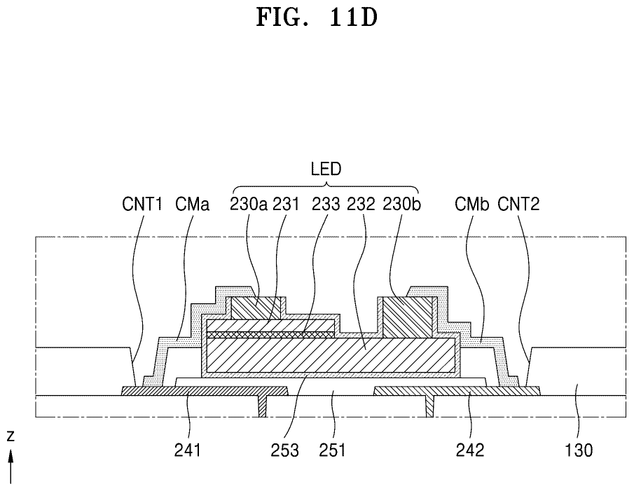

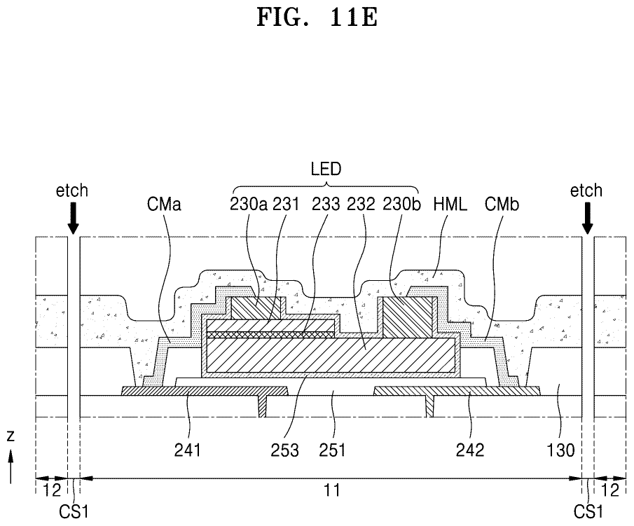

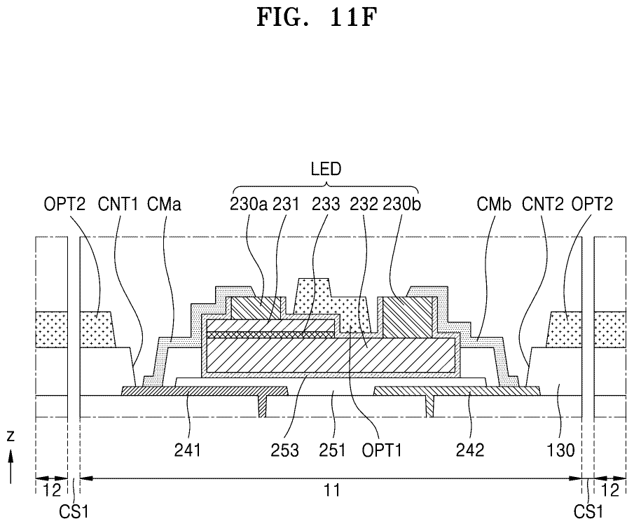

FIGS. 11A to 11F are cross-sectional views schematically illustrating processes of manufacturing the display device 1 according to an embodiment of the disclosure.

First, referring to FIG. 11A, the first electrode pad 241 and the second electrode pad 242 may be formed on the third organic insulating layer 125. A lower structure of the third organic insulating layer 125 is omitted but may have the same structure as described above with reference to FIG. 10.

The adhesive layer 251 may be disposed on the first electrode pad 241 and the second electrode pad 242, and the light-emitting element LED may be attached to the first electrode pad 241 and the second electrode pad 242 by using the adhesive layer 251.

Thereafter, referring to FIG. 11B, the organic insulating film 130 may be formed to cover the first electrode pad 241 and the second electrode pad 242. A portion of the light-emitting element LED may have an embedded structure by the organic insulating film 130.

Then, referring to FIG. 11C, the first contact hole CNT1 and the second contact hole CNT2 may be formed in the organic insulating film 130. A portion of the organic insulating film 130 may be removed to form the first contact hole CNT1 and the second contact hole CNT2, and at least a portion of the first electrode pad 241 and the second electrode pad 242 may be exposed to correspond to the first contact hole CNT1 and the second contact hole CNT2.

Thereafter, referring to FIG. 11D, the first electrode pad 241 may be electrically connected to the first electrode 230a and the second electrode pad 242 may be electrically connected to the second electrode 230b by patterning the first contact electrode CMa and the second contact electrode CMb. One end portion of the first contact electrode CMa may be connected to the first electrode pad 241 exposed through the first contact hole CNT1, and another end portion of the first contact electrode CMa may be connected to the first electrode 230a. An end portion of the second contact electrode CMb may be connected to the second electrode pad 242 exposed through the second contact hole CNT2, and another end of the second contact electrode CMb may be connected to the second electrode 230b.

Referring to FIG. 11E, a hard mask process may be performed thereafter. A hard mask layer HML may be formed to completely cover an upper portion of the light-emitting element LED. The hard mask layer HML may include a transparent conductive material. For example, the hard mask layer HML may include a TCO, such as ITO, IZO, ZnO, In₂O₃, IGO, or AZO.

The substrate (refer to FIG. 5) may be patterned into the first island portion 11 and the first bridge portion 12 through a hard mask process. In other words, portions and layers of the substrate 100 corresponding to the first opening portion CS1 may be removed through the hard mask process, and the shapes of the first island portion 11 and the first bridge portion 12 may be implemented.

Referring to FIG. 11F, the hard mask layer HML may be removed after the hard mask process is completed. Thereafter, the first organic pattern OPT1 may be formed on the light-emitting element LED. The first organic pattern OPT1 may be patterned to pass between the first electrode 230a and the second electrode 230b of the light-emitting element LED.

Also, the second organic pattern OPT2 and the third organic pattern OPT3 may be formed on the organic insulating film 130. The first organic pattern OPT1, the second organic pattern OPT2, and the third organic pattern OPT3 may be formed by the same process. In other words, the first organic pattern OPT1, the second organic pattern OPT2, and the third organic pattern OPT3 may be formed by forming an organic material layer (not shown) for forming the first organic pattern OPT1, the second organic pattern OPT2, and the third organic pattern OPT3 on the entire surface of the substrate 100 and patterning the organic material layer while remaining the first organic pattern OPT1, the second organic pattern OPT2, and the third organic pattern OPT3. Accordingly, the first organic pattern OPT1, the second organic pattern OPT2, and the third organic pattern OPT3 may be formed as an integral body.

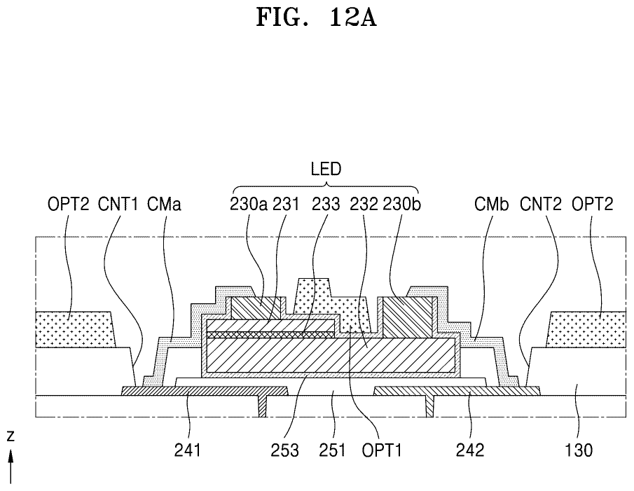

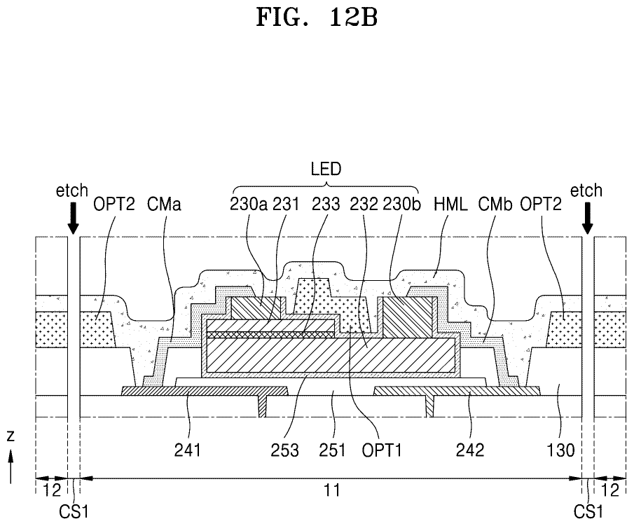

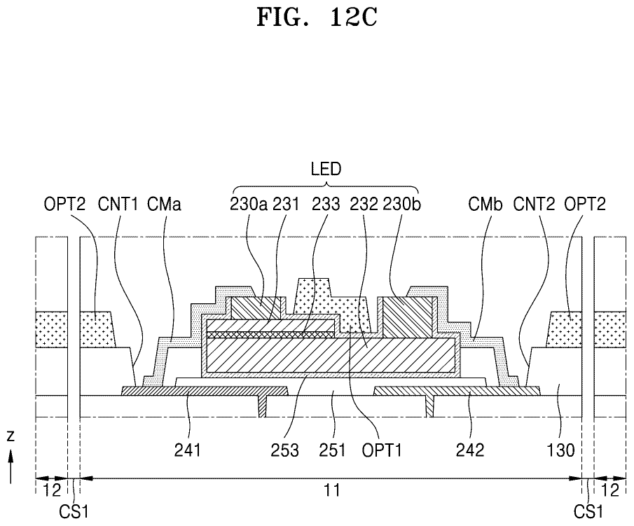

FIGS. 12A to 12C are cross-sectional views schematically illustrating processes of manufacturing the display device 1 according to an embodiment of the disclosure.

In an embodiment, the processes from FIGS. 11A to 11C are the same as those described above, but there are differences in the subsequent processes. In FIGS. 12A to 12C, the first organic pattern OPT1 or the like may be formed before the hard mask process.

Referring to FIG. 12A, the first contact electrode CMa and the second contact electrode CMb may be formed. The first contact electrode CMa and the second contact electrode CMb may be formed in the same process as described above with reference to FIG. 11D. Thereafter, the first organic pattern OPT1 may be formed on the light-emitting element LED. The first organic pattern OPT1 may be patterned to pass between the first electrode 230a and the second electrode 230b of the light-emitting element LED. Also, the second organic pattern OPT2 and the third organic pattern OPT3 may be formed on the organic insulating film 130. As described above with reference to FIG. 11F, the first organic pattern OPT1, the second organic pattern OPT2, and the third organic pattern OPT3 may be formed by the same process.

Referring to FIG. 12B, the hard mask process may be performed thereafter. The hard mask layer HML may be formed on the first organic pattern OPT1, the second organic pattern OPT2, and the third organic pattern OPT3. The hard mask layer HML may be formed to entirely cover the first organic pattern OPT1, the second organic pattern OPT2, the third organic pattern OPT3, and the light-emitting element LED. The substrate (refer to FIG. 5) may be patterned into the first island portion 11 and the first bridge portion 12 through the hard mask process. In other words, portions and layers of the substrate 100 corresponding to the first opening portion CS1 may be removed through the hard mask process, and the shapes of the first island portion 11 and the first bridge portion 12 may be implemented.

Referring to FIG. 12C, the hard mask layer HML may be removed after the hard mask process is completed.

In an embodiment, the hard mask layer HML may include a transparent conductive material. In the manufacturing processes described with reference to FIGS. 12A to 12C, the first organic pattern OPT1 may be formed before the hard mask process. As the first organic pattern OPT1 is disposed between the first electrode 230a and the second electrode 230b, a short circuit may be prevented from occurring between the first electrode 230a and the second electrode 230b due to residues that exist as the residue layer rd (refer to FIG. 9) without removing a portion of the hard mask layer HML between the first electrode 230a and the second electrode 230b.

The display device 1 according to the embodiments described above may be used in various electronic devices that may provide images. Here, the electronic devices refer to devices that may provide certain images by using electricity.

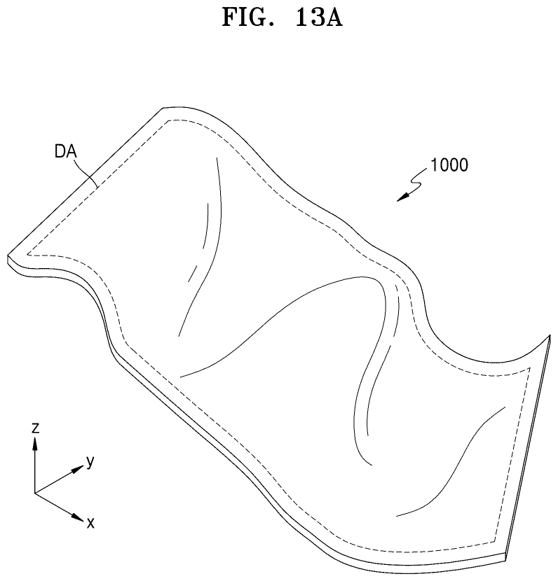

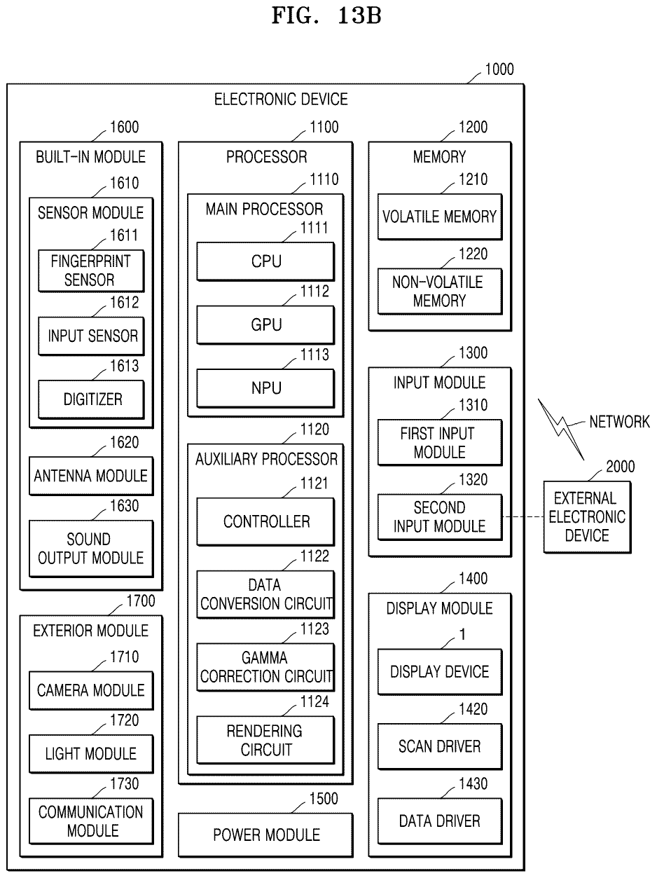

FIG. 13A is a schematic perspective view of an electronic device 1000 including a display device according to an embodiment of the disclosure, and FIG. 13B is a schematic block diagram of the electronic device 1000 including the display device 1 according to an embodiment of the disclosure.

Referring to FIG. 13A, the electronic device 1000 may freely be transformed three-dimensionally and provide a three-dimensional image surface through the display area DA. The electronic device 1000 being freely transformed three-dimensionally is distinguished from an operation of an electronic device having a rollable display device, such as a case in which the entire display area is recognized by a user while a portion of a rolled-up display area is recognized by the user and then another portion of the rolled-up display area is unfolded (or a case in which only a portion of the display area is recognized while the entire portion of the unfolded display area is recognized to the user and then the display area is rolled up). The electronic device 1000 according to embodiments of the disclosure may exhibit transformation such that the area of the entire display area DA increases or decreases again while the electronic device 1000 is transformed in an x direction, a y direction, and/or a z direction.

Referring to FIG. 13B, the electronic device 1000 may include a processor 1100, a memory 1200, an input module 1300, a display module 1400, a power module 1500, a built-in module 1600, and an exterior module 1700. According to an embodiment, the electronic device 1000 may have at least one of the components described above omitted, or one or more other components may be added. According to an embodiment, some of the components described above (for example, the built-in module 1600) may be integrated into another component (for example, the display module 1400).

The processor 1100 may execute software to control at least one other component (e.g., a hardware or software component) of the electronic device 1000 connected to the processor 1100 and may perform various data processing or calculations. According to an embodiment, as at least a part of data processing or calculation, the processor 1100 may store commands or data received from another component (e.g., the input module 1300, a sensor module 1610, or a communication module 1730) in volatile memory 1210, process commands or data stored in the volatile memory 1210, and store resulting data in non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphics processing unit (GPU) 1112, a communication processor (CP), and an image signal processor (ISP). The main processor 1110 may also further include a neural processing unit (NPU) 1113. An NPU is a processor specialized in processing of artificial intelligence models, and the artificial intelligence models may be created through machine learning. An artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the above, but is not limited to the examples described above. An artificial intelligence model may additionally or alternatively include a software structure in addition to a hardware structure. At least two of the processing units and processors described above may be implemented as a single integrated configuration (for example, a single chip) or may each be implemented as an independent configuration (for example, multiple chips).

The auxiliary processor 1120 may include a controller 1121. The controller 1121 may include an interface conversion circuit and a timing control circuit. The controller 1121 may receive an image signal from the main processor 1110 and convert a data format of the image signal to match the interface specifications with the display module 1400 to output the image data. The controller 1121 may output various types of control signals necessary for driving the display module 1400.

The auxiliary processor 1120 may further include data processing circuits such as a data conversion circuit 1122, a gamma correction circuit 1123, and a rendering circuit 1124. The data conversion circuit 1122 may receive image data from the controller 1121 and compensate for the image data so that an image is displayed at a desired brightness according to the characteristics of the electronic device 1000 or the user's setting or convert the image data for reduction in power consumption or compensation for afterimages. The gamma correction circuit 1123 may convert image data or a gamma reference voltage so that an image displayed on the electronic device 1000 has a desired gamma characteristic. The rendering circuit 1124 may receive image data from the controller 1121 and render the image data by considering pixel arrangements of the display device 1 applied to the electronic device 1000. At least one of the data conversion circuit 1122, the gamma correction circuit 1123, and the rendering circuit 1124 may be integrated into another component (for example, the main processor 1110 or the controller 1121). In an embodiment, the auxiliary processor 1120 may be integrated into a data driver 1430.

The memory 1200 may store various pieces of data used by at least one component (e.g., the processor 1100 or the sensor module 1610) of the electronic device 1000 and input data or output data with respect to commands related thereto. The memory 1200 may include at least one or more of the volatile memory 1210 and the non-volatile memory 1220.

The input module 1300 may receive commands or data to be used in a component of the electronic device 1000 (e.g., the processor 1100, the sensor module 1610, or a sound output module 1630), from the outside of the electronic device 1000 (e.g., a user or an external electronic device 2000).

The input module 1300 may include a first input module 1310 to which a command or data is input from the user and a second input module 1320 to which a command or data is input from the external electronic device 2000.

The first input module 1310 may include a microphone, a mouse, a keyboard, or a pen (e.g., a passive pen or an active pen). The first input module 1310 may include a mechanical input unit or a touch input unit such as a button, a dome switch, a jog wheel, a jog switch, or the like located on a back surface or a side surface of the electronic device 1000. The touch input unit may include a touch screen layer of the display device 1.

The second input module 1320 may be connected to various types of external electronic devices 2000 connected to the electronic device 1000 via a wired or wireless manner. According to an embodiment, the second input module 1320 may include a high-definition multimedia interface (HDMI), a universal serial bus (USB) interface, a secure digital (SD) card interface, or an audio interface. The second input module 1320 may include a connector capable of physically connecting the electronic device 1000 to the external electronic device 2000, for example, an HDMI connector, a USB connector, an SD card connector, or an audio connector (e.g., a headphone connector). The electronic device 1000 may perform appropriate control related to the connected external electronic device 2000 in response to the external electronic device 2000 being connected to the second input module 1320.

The display module 1400 visually provides information to the user. The display module 1400 may include the display device 1, a scan driver 1420, and the data driver 1430.

The display device 1 displays (outputs) information processed by the electronic device 1000. The display device 1 may display execution screen information of an application driven by the electronic device 1000 or a user interface (UI) or graphic user interface (GUI) according to the execution screen information.

The scan driver 1420 may be mounted in the display device 1 as a driving chip. Alternatively, the scan driver 1420 may be directly formed in the display device 1. For example, the scan driver 1420 may include an amorphous silicon TFT gate driver circuit (ASG), a low temperature polycrystalline silicon (LTPS) TFT gate driver circuit, or an oxide semiconductor TFT gate driver circuit (OSG) embedded in the display device 1. The scan driver 1420 receives a control signal from the controller 1121 and outputs a scan signal to the display device 1 in response to the control signal.

The display device 1 may further include an emission control driver. The emission control driver outputs an emission control signal to the display device 1 in response to a control signal received from the controller 1121. The emission control driver may be formed separately from the scan driver 1420 or may be integrated into the scan driver 1420.

The data driver 1430 receives a control signal from the controller 1121, converts image data into data voltages in a form of analog voltages, and then outputs the data voltages to the display device 1.

The data driver 1430 may be integrated with some components of the auxiliary processor 1120. For example, the data driver 1430 may be provided as a timing controller embedded driver integrated circuit (IC) including the controller 1121.

The power module 1500 supplies power to the components of the electronic device 1000. The power module 1500 may include a battery that charges the power voltage. In addition, the power module 1500 may have a connection port, and the connection port may be included in the second input module 1320 to which an external charger that supplies power to charge the battery is connected. Alternatively, the power module 1500 may include a wireless power transmission/reception member to enable wireless charging of the battery. The wireless power transmission/reception member may include a plurality of antenna radiators in a coil shape. The power module 1500 may include a power management integrated circuit (PMIC). The PMIC supplies optimized power to each component of the electronic device 1000.

The electronic device 1000 may further include the built-in module 1600 and the exterior module 1700. The built-in module 1600 may include the sensor module 1610, an antenna module 1620, and the sound output module 1630. The exterior module 1700 may include a camera module 1710, a light module 1720, and/or the communication module 1730.

The sensor module 1610 may include touch electrodes and a touch sensor driver of a touch screen layer of the display device 1. The sensor module 1610 may sense an input by the user's body or an input by a pen and generate an electrical signal or data value corresponding to the input. The sensor module 1610 may include at least one of a fingerprint sensor 1611, an input sensor 1612, a digitizer 1613, and a strain sensor 1614.

The fingerprint sensor 1611 may generate a data value corresponding to the fingerprint of the user. The fingerprint sensor 1611 may include any one of fingerprint sensors in an optical method or capacitive method.

The input sensor 1612 may generate a data value corresponding to coordinate information of input by the user's body or input by a pen. The input sensor 1612 generates an amount of change in capacitance due to an input into a data value. The input sensor 1612 may sense an input by a passive pen or transmit/receive data to/from an active pen.

The input sensor 1612 may also measure biological signals, such as blood pressure, moisture, or body fat. For example, when the user contacts a part of his/her body to a sensor layer or sensing panel and does not move a certain period of time, the input sensor 1612 may sense a bio-signal based on a change in electric field caused by the body part and output information desired by the user to the display module 1400.

The digitizer 1613 may generate a data value corresponding to coordinate information of an input by a pen. The digitizer 1613 generates an electromagnetic change amount due to an input into a data value. The digitizer 1613 may sense an input by a passive pen or transmit/receive data to/from an active pen.

The strain sensor 1614 may include layers, patterns, or lines of which a measurable physical quantity changes according to the elongation of the display device 1. For example, the strain sensor 1614 may include lines of which the resistance and/or capacitance changes due to stretching and recovering of a display panel DP. In another embodiment, the strain sensor 1614 may include an optical layer or optical pattern of which the transmittance and/or reflectance changes due to stretching of the display device 1.

Based on the physical quantity according to the stretching of the display device 1, which is measured by the strain sensor 1614, the electronic device 1000 may improve the image quality of an image implemented in the display device 1 or control the display device 1. A control operation of the display device 1 may include, for example, an operation of displaying an operation image to protect the display device 1, an operation of cutting off a voltage for driving the display device 1, or an operation of stopping a stretching operation of the display device 1.

In an embodiment, at least one of the fingerprint sensor 1611, the input sensor 1612, the digitizer 1613, and the strain sensor 1614 may be built into the display device 1. For example, at least one of the fingerprint sensor 1611, the input sensor 1612, the digitizer 1613, and the strain sensor 1614 may be formed through a process that is continuous with a process of forming pixel circuits and light-emitting diodes of the display device 1. Therefore, the display device 1 may function as one of one of the input modules 1300 providing an input interface between the electronic device 1000 and the user and at the same time, may function as the display module 1400 providing an output interface between the electronic device 1000 and the user.

In an embodiment, at least two of the fingerprint sensor 1611, the input sensor 1612, the digitizer 1613, and the strain sensor 1614 may be formed to be integrated into one sensing panel through the same process. In an embodiment, the sensing panel may be disposed between the display device 1 and a window disposed on an upper side of the display device 1, but the disclosure is not limited thereto.

The antenna module 1620 may include one or more antennas for transmitting signals or power to the outside or receiving signals or power from the outside. According to an embodiment, the communication module 1730 may transmit a signal to an external electronic device or receive a signal from the external electronic device through an antenna suitable for a communication method. An antenna pattern of the antenna module 1620 may also be integrated into one component of the display module 1400 (e.g., the display device 1) or the input sensor 1612.

The sound output module 1630 is a device for outputting sound signals to the outside of the electronic device 1000, which may output sound data received from the communication module 1730 in a call signal reception mode, call mode, recording mode, voice recognition mode, or broadcast reception mode or sound data stored in the memory 1200. The sound output module 1630 may output sound signals related to functions (for example, a call signal reception sound, a message reception sound, or the like) performed by the electronic device 1000. The sound output module 1630 may include a receiver and a speaker. At least one of the receiver and the speaker may be a sound generating device which is attached to a lower portion of the display device 1 and vibrates the display device 1 to output sound. The sound generating device may be a piezoelectric element or a piezoelectric actuator which contracts and expands according to an electrical signal, or may be an exciter that vibrates the display device 1 by generating a magnetic force using a voice coil.

The camera module 1710 may capture still images and videos. According to an embodiment, the camera module 1710 may include one or more lenses, image sensors, or image signal processors. The camera module 1710 may further include an infrared camera that may measure the presence or absence of the user, the user's position, the line of sight of the user, or the like.

The light module 1720 may output signal to notify the occurrence of an event by using light of a light source or provide light for image acquisition. Here, examples of the occurrences of events may include reception of a message, reception of a call signal, missing a call, a notification, a calendar reminder, reception of an email, or notification of battery charge level information. The light module 1720 may include a light-emitting diode or xenon lamp. The light module 1720 may emit light of a single color or multiple colors to the front surface or rear surface of the electronic device 1000. The light module 1720 may operate in conjunction with the camera module 1710 or independently.

The communication module 1730 may support establishment of a wired or wireless communication channel between the electronic device 1000 and the external electronic device 2000 and performance of communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module or a power line communication module. The communication module 1730 may transmit and receive wireless signals on the Internet by using at least one of Wireless LAN (WLAN), Wireless-Fidelity (Wi-Fi), Wi-Fi Direct, and Digital Living Network Alliance (DLNA) technologies. Also, the communication module 1730 may support short-range communication by using at least one of Bluetooth™, radio frequency identification (RFID), infrared data association (IrDA), ultra wideband (UWB), ZigBee, near-field communication (NFC), Wi-Fi, Wi-Fi Direct, and wireless universal serial bus (USB) technology. The various types of communication module 1730 described above may be implemented as a single chip or as separate chips.

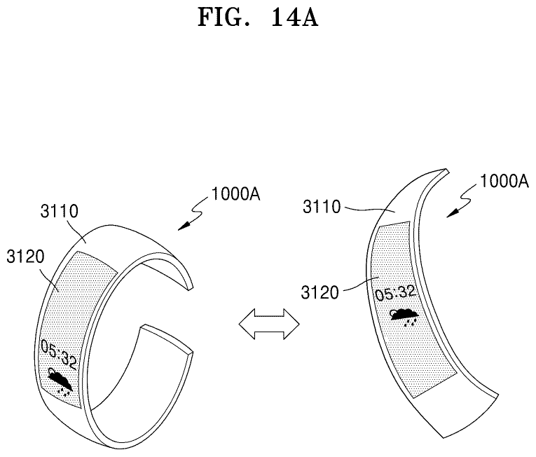

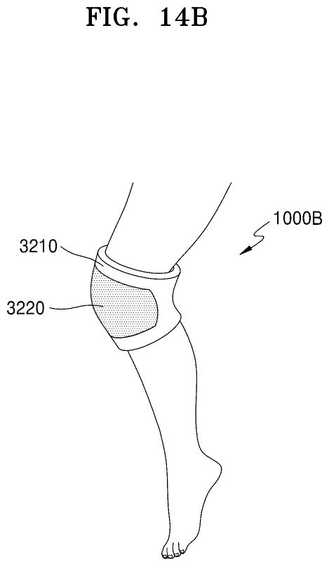

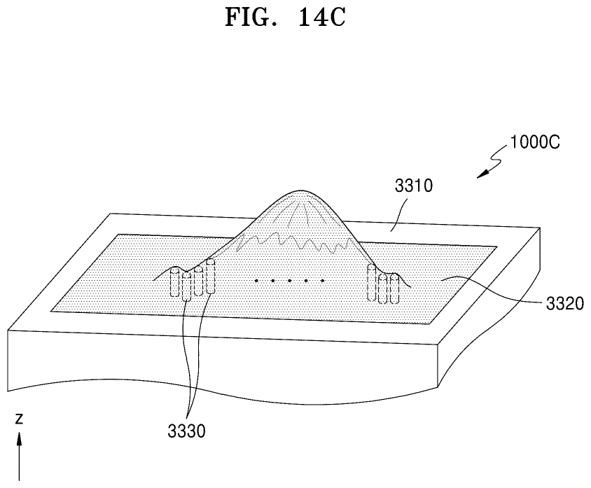

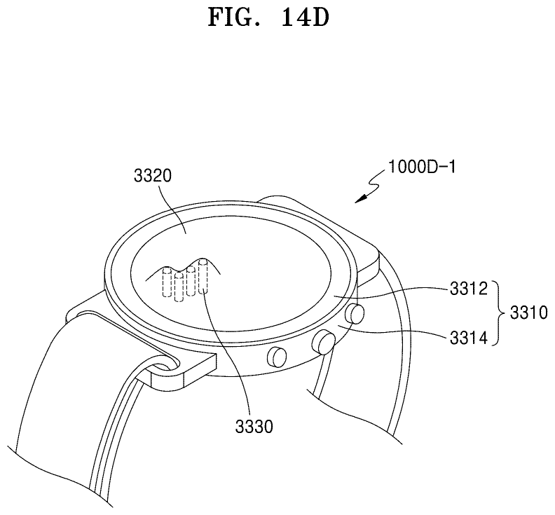

FIGS. 14A to 14D are schematic perspective views showing embodiments of an electronic device including a display device, respectively, according to an embodiment of the disclosure.

Referring to FIG. 14A, a display device according to an embodiment may be used in a wearable electronic device 1000A which may be worn on a part of a user's body. The wearable electronic device 1000A may include a body portion 3110 and a display portion 3120 provided in the body portion 3110. A display device according to embodiments of the disclosure may be used as the display portion 3120 of the wearable electronic device 1000A. As shown in FIG. 14A, the wearable electronic device 1000A may be transformable. In an embodiment, the wearable electronic device 1000A may be used as a smart watch or a smartphone depending on the user's choice.

FIG. 14B shows a medical electronic device 1000B. In an embodiment, the medical electronic device 1000B may include a body portion 3210 and a light-emitting portion 3220. A display device according to embodiments of the disclosure may be used as the light-emitting portion 3220 of the medical electronic device 1000B. The light-emitting portion 3220 may emit light of a certain wavelength band (e.g., infrared light, visible light ray, or the like) to the body of a patient. In an embodiment, the body portion 3210 may include a stretchable and recoverable fiber material and may have a structure that the light-emitting portion 3220 may be worn on the user's body.

FIG. 14C shows an educational electronic device 1000C. In an embodiment, the educational electronic device 1000C may include a display portion 3320 provided in a frame 3310. The display portion 3320 may use a display device according to embodiments of the disclosure. The display portion 3320 may provide images, such as a sea with waves, a mountain covered with snow, or a volcano with flowing lava, and at this time, the display portion 3320 may extend in a height direction (e.g., a z direction) by reflecting the height of the waves, the mountain, or the volcano. In some embodiments, a portion of the display portion 3320 may three-dimensionally show the movement of lava by sequentially changing the height along a direction in which the lava flows. The educational electronic device 1000C may include a plurality of pins (or stroke portions) 3330 disposed on the rear surface of the display portion 3320 so that the display portion 3320 may be stretched in the height direction. While the pins 3330 move along a third direction (e.g., a z direction or a-z direction), an image displayed on the display portion 3320 may be implemented to have a three-dimensional height. FIG. 13 shows the educational electronic device 1000C, but the use is not limited as long as the apparatus provides certain image information.

FIG. 14D shows that a display device is used in a wearable electronic device 1000D-1, such as a smart watch. In an embodiment, a display device corresponding to a display portion 3320 of the electronic device 1000D-1 is three-dimensionally stretchable and thus may provide various pieces of haptic information to a user. In an embodiment, the electronic device 1000D-1 may provide haptic information, such as braille display for visually impaired or tactile stimulation linked to an image, by using a plurality of pins (or stroke portions) 3330 disposed below the display portion 3320. The display device forming the display portion 3320 is three-dimensionally stretchable and thus may provide the user with the haptic information described above.

The embodiments described with reference to FIGS. 14A to 14D describe the electronic devices 1000, 1000B, 1000C, and 1000D-1 in which the display portion is three-dimensionally transformed, but the disclosure is not limited thereto. As to be described below, a display device according to embodiments of the disclosure may be used in an electronic device in which a portion capable of displaying images (e.g., a screen) is fixed.

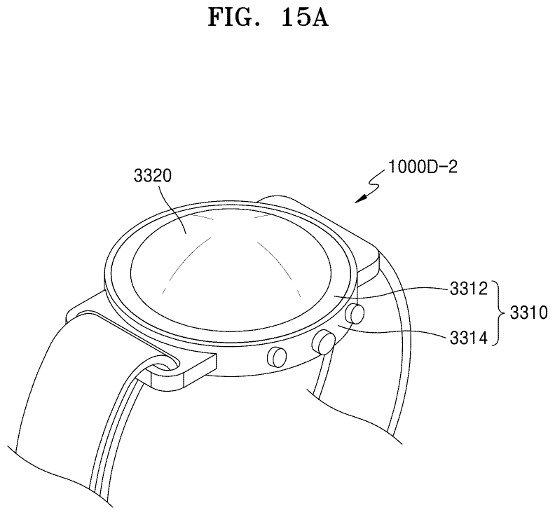

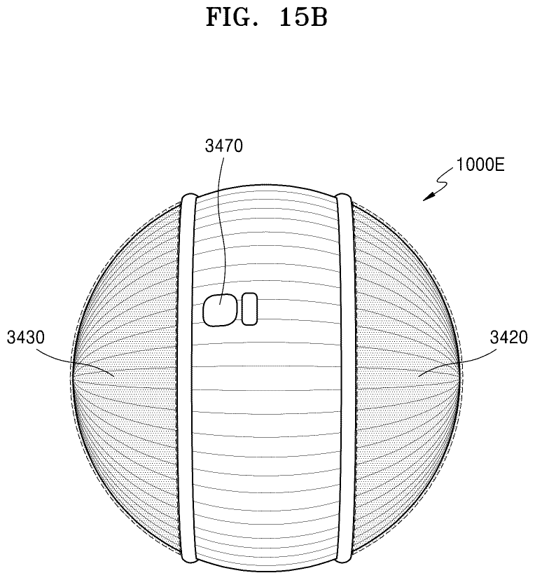

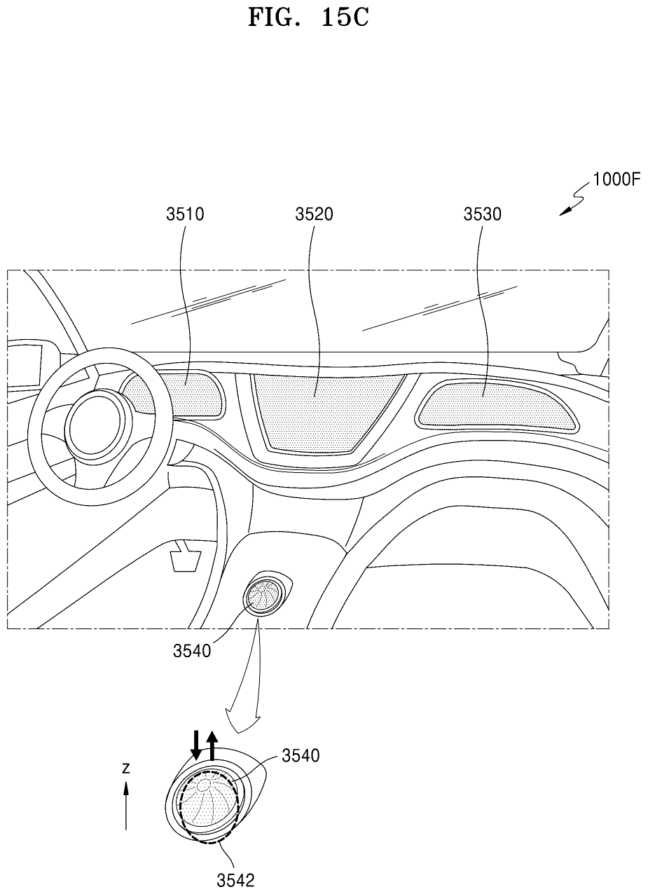

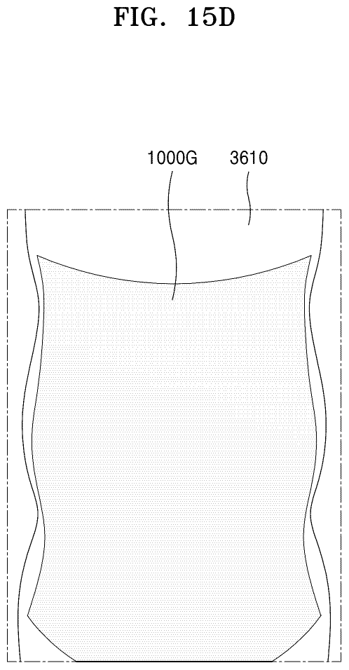

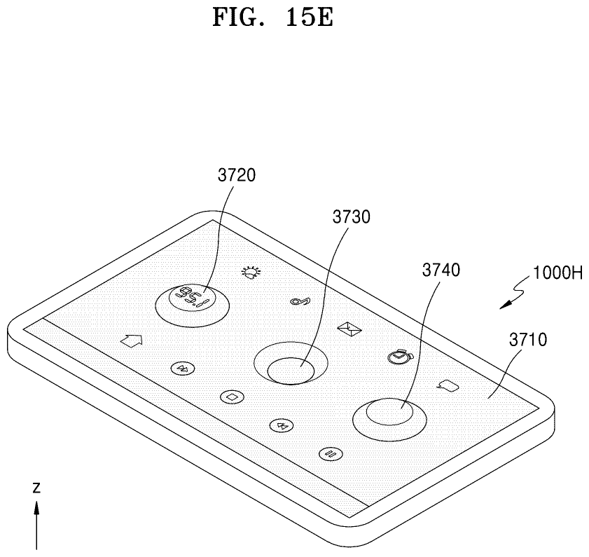

FIGS. 15A to 15E are schematic perspective views illustrating electronic devices, respectively, according to an embodiment of the disclosure.

FIG. 15A shows that a display device is used in a wearable electronic device 1000D-2, such as a smart watch. The electronic device 1000D-2 shown in FIG. 15A includes the display portion 3320, but the display portion 3320 may have a three-dimensional dome shape (or a hemispherical shape). In a process of manufacturing the electronic device 1000D-2, a display device may be assembled into a body frame having a dome shape, and at this time, the display device is three-dimensionally stretchable and thus may be assembled in a stretched state according to the shape of the body frame having the dome shape.

FIG. 15B shows that an electronic device 1000E according to an embodiment of the disclosure includes a robot. The robot may recognize movement or objects by using the camera module 1710 and may display certain images through display portions 3420 and 3430. In some embodiments, as described above, because a display device according to an embodiment of the disclosure may be stretched in various directions, the display device may be assembled into a body frame having a hemispherical shape, and accordingly, the robot may include the display portions 3420 and 3430 having hemispherical shapes.

FIG. 15C shows a vehicle display device 1000F as an electronic device according to an embodiment of the disclosure. The vehicle display device 1000F may include a cluster 3510, a center information display (CID) 3520, and/or a co-driver display 3530. Because a display device according to an embodiment of the disclosure may be stretched in various directions, the display device may be used in the cluster 3510, the CID 3520, and/or the co-driver display 3530 regardless of the shape of the internal frame of the vehicle.

FIG. 15C shows that the cluster 3510, the CID 3520, and the co-driver display 3530 are separated from each other, but the disclosure is not limited thereto. In another embodiment, two or more selected from the cluster 3510, the CID 3520, and the co-driver display 3530 may be integrally connected to each other.

In some embodiments, the vehicle display device 1000F may include a button 3540 that may display a certain image. Referring to the enlarged view of FIG. 15C, the button 3540 having a hemispherical shape may include an object 3542 that provides the feeling of using while moving in the z direction or the −z direction, and a display device disposed on the object 3542. In some embodiments, when the object 3542 has a three-dimensionally rounded surface, the display device may also have a three-dimensionally rounded surface.

FIG. 15D shows that an electronic device according to an embodiment of the disclosure is an advertising or exhibiting electronic device 1000G. In some embodiments, the advertising or exhibiting electronic device 1000G may be installed on a fixed structure 3610, such as a wall or pillar. When the structure 3610 includes an uneven surface as shown in FIG. 15D, the advertising or exhibiting electronic device 1000G may be disposed along the uneven surface of the structure 3610. In some embodiments, the advertising or exhibiting electronic device 1000G may be installed on the structure 3610 by using a heat shrink film or the like.

FIG. 15E shows that an electronic device 1000H according to an embodiment of the disclosure includes a controller. The controller may include an image-type button. For example, the controller may include first to third button areas 3720, 3730, and 3740 in which a partial area of a display portion 3710 protrudes in a z direction or a-z direction (or is depressed in the z direction). In some embodiments, the first and third button areas 3720 and 3740 may protrude in the z direction, and the second button area 3730 may protrude in the −z direction (or may be depressed in the z direction).

The disclosure has been described with reference to the embodiments shown in the drawings, but these are merely examples, and those skilled in the art will understand that various modifications and equivalent other embodiments are possible therefrom. Accordingly, the true technical protection scope of the disclosure should be determined by the technical concept of the attached patent claims.

### EXPLANATION OF REFERENCE NUMERALS

1: Display device
11: First island portion
12: First bridge portion
100b: Bridge area
100a: Island area
130: Organic insulating film
1000: Electronic device
CS1: First opening portion
OPT1: First organic pattern
OPT3: Second organic pattern
OPT3: Third organic pattern
LED: Light-emitting element
230b: Second electrode
230a: First electrode

What is claimed is:

1. A display device comprising:
a plurality of island portions disposed to be spaced apart from each other and comprising a pixel circuit; and
a plurality of bridge portions, each connecting adjacent island portions among the plurality of island portions to each other,
wherein each of the plurality of island portions comprises:
a first light-emitting element and a second light-emitting element, which are disposed on the island portion and spaced apart from each other; and
a first organic pattern partially overlapping the first light-emitting element and the second light-emitting element in a plan view and continuously disposed on the first light-emitting element and the second light-emitting element to extend in a first direction.

2. The display device of claim 1, further comprising a second organic pattern comprising a same material as the first organic pattern and disposed to surround edges of the island portion in a frame shape.

3. The display device of claim 2, wherein the first organic pattern and the second organic pattern are provided as an integral body.

4. The display device of claim 2, further comprising a third organic pattern comprising the same material as the first organic pattern and disposed on each of the plurality of bridge portions.

5. The display device of claim 4, wherein the first organic pattern, the second organic pattern, and the third organic pattern are provided as an integral body.

6. The display device of claim 1, wherein each of the first light-emitting element and the second light-emitting element comprises an inorganic light-emitting element.

7. The display device of claim 6, wherein each of the first light-emitting element and the second light-emitting element comprises a first semiconductor layer, a second semiconductor layer, an intermediate layer disposed between the first semiconductor layer and the second semiconductor layer, a first electrode positioned on the first semiconductor layer, and a second electrode positioned on the second semiconductor layer.

8. The display device of claim 7, wherein the first organic pattern is disposed to pass between the first electrode and the second electrode, and the first electrode and the second electrode are spaced apart from each other.

9. The display device of claim 7, wherein the first organic pattern does not overlap the first electrode and the second electrode in the plan view.

10. The display device of claim 7, wherein the island portion further comprises a substrate and an organic insulating film positioned on the substrate,
the pixel circuit is disposed on the substrate,
the organic insulating film is disposed on the pixel circuit, and
at least a portion of each of the first light-emitting element and the second light-emitting element is surrounded and embedded in the organic insulating film.

11. The display device of claim 10, wherein the first electrode and the second electrode protrude above an upper surface of the organic insulating film.

12. The display device of claim 10, wherein the pixel circuit comprises a first electrode pad and a second electrode pad, and
the organic insulating film defines a first contact hole and a second contact hole therein exposing the first electrode pad and the second electrode pad, respectively.

13. The display device of claim 12, further comprising:
a first contact electrode electrically connecting the first electrode pad to the first electrode, and
a second contact electrode electrically connecting the second electrode pad to the second electrode.

14. The display device of claim 13, wherein the first contact electrode contacts the first electrode pad in the first contact hole, and the second contact electrode contacts the second electrode pad in the second contact hole.

15. The display device of claim 13, wherein each of the first contact electrode and the second contact electrode comprises a transparent conductive material.

16. The display device of claim 7, wherein the first organic pattern passes between the first electrode and the second electrode.

17. The display device of claim 16, wherein a width of the first organic pattern is equal to or less than a distance between the first electrode and the second electrode.

18. The display device of claim 7, wherein a top surface of the first organic pattern is positioned higher than top surfaces of the first electrode and the second electrode.

19. The display device of claim 1, wherein each of the plurality of bridge portions has a serpentine shape in the plan view.

20. An electronic device including a display device, wherein the display device comprises:
a plurality of island portions disposed to be spaced apart from each other and comprising a pixel circuit; and
a plurality of bridge portions, each connecting adjacent island portions among the plurality of island portions to each other,
wherein each of the plurality of island portions comprises:
a first light-emitting element and a second light-emitting element, which are disposed on the island portion and spaced apart from each other; and
an organic pattern partially overlapping the first light-emitting element and the second light-emitting element in a plan view and continuously disposed on the first light-emitting element and the second light-emitting element to extend in a first direction.
